(19) United States
(12) Patent Application Publication
(10) Pub. No.: US 2024/0001486 A1
(43) Pub. Date: Jan. 4, 2024

(54) SPECTRUM WAVEFORM CONTROL METHOD, LASER APPARATUS, EXPOSURE APPARATUS, AND ELECTRONIC DEVICE MANUFACTURING METHOD

(71) Applicant: Gigaphoton Inc., Tochigi (JP)

(72) Inventors: Takamitsu KOMAKI, Oyama-shi (JP); Toshihiro OGA, Oyama-shi (JP)

(73) Assignee: Gigaphoton Inc., Tochigi (JP)

(21) Appl. No.: 18/467,361

(22) Filed: Sep. 14, 2023

Related U.S. Application Data
(63) Continuation of application No. PCT/JP2021/015234, filed on Apr. 12, 2021.

(51) Int. Cl. B23K 26/06; B23K 26/70; G02B 27/10

(52) U.S. Cl. CPC B23K 26/0648; B23K 26/707; B23K 26/0626; G02B 27/1093; B23K 26/0643; B23K 26/0652; B23K 2101/40

(57) ABSTRACT

A control method for a spectrum waveform of a laser beam output from a laser apparatus to an exposure apparatus includes acquiring a longitudinal chromatic aberration of the exposure apparatus, setting a target value of an evaluation value of the spectrum waveform by using a relation between the longitudinal chromatic aberration and the evaluation value, and controlling the spectrum waveform by using the target value.

### CROSS-REFERENCE TO RELATED APPLICATIONS

The present application is a continuation application of International Application No. PCT/JP2021/015234, filed on Apr. 12, 2021, the entire contents of which are hereby incorporated by reference.

### BACKGROUND

### 1. Technical Field

The present disclosure relates to a spectrum waveform control method, a laser apparatus, an exposure apparatus, and an electronic device manufacturing method.

### 2. Related Art

Recently, in a semiconductor exposure apparatus, resolving power improvement has been requested along with miniaturization and high integration of a semiconductor integrated circuit. Thus, the wavelength of light emitted from an exposure light source has been shortened. Examples of a gas laser apparatus for exposure include a KrF excimer laser apparatus configured to output a laser beam having a wavelength of approximately 248 nm and an ArF excimer laser apparatus configured to output a laser beam having a wavelength of approximately 193 nm.

The KrF excimer laser apparatus and the ArF excimer laser apparatus have a wide spectrum line width of 350 pm to 400 pm for spontaneous oscillation light. Thus, chromatic aberration occurs in some cases when a projection lens is made of a material that transmits ultraviolet light such as KrF and ArF laser beams. This can lead to resolving power decrease. Thus, the spectrum line width of a laser beam output from the gas laser apparatus needs to be narrowed so that chromatic aberration becomes negligible. To narrow the spectrum line width, a line narrowing module (LNM) including a line narrowing element (for example, an etalon or a grating) is provided in a laser resonator of the gas laser apparatus in some cases. In the following, a gas laser apparatus that achieves narrowing of the spectrum line width is referred to as a line narrowed gas laser apparatus.

### LIST OF DOCUMENTS

### Patent Documents

Patent Document 1: International Patent Publication No. 2002/073670
Patent Document 2: US Patent Application Publication No. 2011/200922

### SUMMARY

A spectrum waveform control method according to one aspect of the present disclosure is a control method for a spectrum waveform of a laser beam output from a laser apparatus to an exposure apparatus and includes acquiring a longitudinal chromatic aberration of the exposure apparatus, setting a target value of an evaluation value of the spectrum waveform by using a relation between the longitudinal chromatic aberration and the evaluation value, and controlling the spectrum waveform by using the target value.

A laser apparatus according to one aspect of the present disclosure is a laser apparatus connectable to an exposure apparatus and includes a laser oscillator configured to output a laser beam, a spectrum waveform adjuster configured to adjust a spectrum waveform of the laser beam, and a processor configured to acquire a longitudinal chromatic aberration of the exposure apparatus, to set a target value of an evaluation value of the spectrum waveform by using a relation between the longitudinal chromatic aberration and the evaluation value, and to control the spectrum waveform adjuster by using the target value.

An exposure apparatus according to one aspect of the present disclosure is an exposure apparatus connectable to a laser apparatus and includes a projection optical system configured to form an image on a wafer surface by using a laser beam output from the laser apparatus, a sensor configured to measure contrast on the wafer surface, a stage configured to move the sensor along an optical path axis of the laser beam, and a processor configured to acquire a longitudinal chromatic aberration of the exposure apparatus by using the stage and the sensor, to set a target value of an evaluation value of a spectrum waveform of the laser beam by using a relation between the longitudinal chromatic aberration and the evaluation value, and to transmit the target value to the laser apparatus.

A method of manufacturing an electronic device according to one aspect of the present disclosure includes acquiring a longitudinal chromatic aberration of an exposure apparatus, setting a target value of an evaluation value of a spectrum waveform of a laser beam by using a relation between the longitudinal chromatic aberration and the evaluation value, the laser beam being output from a laser apparatus connected to the exposure apparatus, outputting a laser beam generated by controlling the spectrum waveform by using the target value to the exposure apparatus, and exposing a photosensitive substrate to the laser beam in the exposure apparatus to manufacture the electronic device.

### BRIEF DESCRIPTION OF THE DRAWINGS

Embodiments of the present disclosure will be described below as examples with reference to the accompanying drawings.

FIG. 1 schematically illustrates the configuration of an exposure system in a comparative example.

FIG. 2 schematically illustrates the configuration of a laser apparatus according to the comparative example.

FIG. 3 is a block diagram for description of functions of a spectrum measurement control processor in the comparative example.

FIG. 4 is a graph illustrating an example of an estimated spectrum waveform I(λ) of a laser beam.

FIG. 5 schematically illustrates difference in focusing through a projection optical system in accordance with the spectrum of a laser beam.

FIG. 6 is a graph illustrating distribution of the focusing position of a laser beam in an exposure apparatus.

FIG. 7 schematically illustrates difference in focusing through the projection optical system in accordance with a longitudinal chromatic aberration K.

FIG. 8 is a graph illustrating the relation between the longitudinal chromatic aberration K and contrast at a first position F1 in a case of a constant spectrum waveform.

FIG. 9 schematically illustrates the configuration of a laser apparatus according to an embodiment of the present disclosure.

FIG. 10 illustrates an example of a reticle pattern used for measurement of the longitudinal chromatic aberration K.

FIG. 11 schematically illustrates part of an exposure apparatus according to the embodiment.

FIG. 12 illustrates light intensity distribution measured by a sensor when a wafer surface is moved to a position Za.

FIG. 13 illustrates light intensity distribution measured by the sensor when the wafer surface is moved to a position Zb.

FIG. 14 illustrates light intensity distribution measured by the sensor when the wafer surface is moved to a position Zc.

FIG. 15 is a graph illustrating an example of a result of contrast measurement while a workpiece table is moved in a direction parallel to a Z axis.

FIG. 16 is a graph illustrating the relation between the position of the wafer surface and contrast in a case in which two different wavelengths are used.

FIG. 17 is a graph illustrating another example of the spectrum waveform of a laser beam.

FIG. 18 is a graph illustrating another example of the spectrum waveform of a laser beam.

FIG. 19 illustrates a rectangular imaging pattern used for imaging performance evaluation.

FIG. 20 is a graph illustrating simulation results of imaging performance in the exposure apparatus.

FIG. 21 is a graph illustrating simulation results of imaging performance in the exposure apparatus.

FIG. 22 is a flowchart illustrating the process of measurement of a spectrum evaluation value V in the embodiment.

FIG. 23 illustrates an imaging pattern used for usefulness comparison between the spectrum evaluation value V and a spectrum line width E95.

FIG. 24 is a graph illustrating the relation between the spectrum line width E95 and ΔCD in the imaging pattern in FIG. 23.

FIG. 25 is a graph illustrating the relation between the spectrum evaluation value V and ΔCD in the imaging pattern in FIG. 23.

FIG. 26 illustrates another imaging pattern used for usefulness comparison between the spectrum evaluation value V and the spectrum line width E95.

FIG. 27 is a graph illustrating the relation between the spectrum line width E95 and ΔCD in the imaging pattern in FIG. 26.

FIG. 28 is a graph illustrating the relation between the spectrum evaluation value V and ΔCD in the imaging pattern in FIG. 26.

FIG. 29 is a graph illustrating the relation between the spectrum evaluation value V of Expression 4 and ΔCD in the imaging pattern in FIG. 23.

FIG. 30 is a graph illustrating the relation between the spectrum evaluation value V of Expression 4 and ΔCD in the imaging pattern in FIG. 26.

FIG. 31 is a graph illustrating the relation between the longitudinal chromatic aberration K and a focusing distribution evaluation value D_{K} in a case of a constant spectrum waveform.

FIG. 32 is a graph illustrating the relation set in the embodiment between the longitudinal chromatic aberration K and the spectrum evaluation value V.

FIG. 33 illustrates a table representing the relation set in the embodiment between the longitudinal chromatic aberration K and the spectrum evaluation value V.

FIG. 34 is a graph illustrating the relation between the longitudinal chromatic aberration K and contrast at the focusing position in a case in which the spectrum evaluation value V is set so that the focusing distribution evaluation value D_{K} is kept constant.

FIG. 35 is a flowchart illustrating the process of table generation in the embodiment.

FIG. 36 is a flowchart illustrating the process of spectrum control in the embodiment.

FIG. 37 is a flowchart illustrating processing that the laser apparatus acquires the longitudinal chromatic aberration K.

FIG. 38 is a flowchart illustrating processing that the exposure apparatus acquires the longitudinal chromatic aberration K.

FIG. 39 is a flowchart illustrating processing that the laser apparatus performs spectrum control by using a target value Vt.

FIG. 40 is a flowchart illustrating processing that the exposure apparatus performs spectrum control by using the target value Vt.

### DESCRIPTION OF EMBODIMENTS

### <Contents>

1. Comparative example
   1.1 Configuration of exposure apparatus 100
   1.2 Operation of exposure apparatus 100
   1.3 Configuration of laser apparatus 1
      1.3.1 Laser oscillator 20
      1.3.2 Monitor module 16
      1.3.3 Various kinds of processing devices
   1.4 Operation
      1.4.1 Laser control processor 30
      1.4.2 Laser oscillator 20
      1.4.3 Monitor module 16
      1.4.4 Wavelength measurement control unit 50
      1.4.5 Spectrum measurement control processor 60
   1.5 Problem of comparative example
2. Laser apparatus 1a configured to control spectrum waveform in accordance with longitudinal chromatic aberration K
   2.1 Configuration
   2.2 Measurement of longitudinal chromatic aberration K
   2.3 Measurement of spectrum evaluation value V
   2.4 Comparison between spectrum evaluation value V and spectrum line width E95
   2.5 Modification of spectrum evaluation value V
   2.6 Control of spectrum evaluation value V in accordance with longitudinal chromatic aberration K
   2.7 Generation of table
   2.8 Operation of spectrum control
      2.8.1 Acquisition of longitudinal chromatic aberration K by laser apparatus 1a
      2.8.2 Acquisition of longitudinal chromatic aberration K by exposure apparatus 100
      2.8.3 Spectrum control using target value Vt by laser apparatus 1a
      2.8.4 Spectrum control using target value Vt by exposure apparatus 100
   2.9 Effect
3. Other

Embodiments of the present disclosure will be described below in detail with reference to the accompanying drawings. The embodiments described below are examples of the present disclosure, and do not limit the contents of the present disclosure. Not all configurations and operations described in each embodiment are necessarily essential as configurations and operations of the present disclosure. Components identical to each other are denoted by an identical reference sign, and duplicate description thereof will be omitted.

### 1. Comparative Example

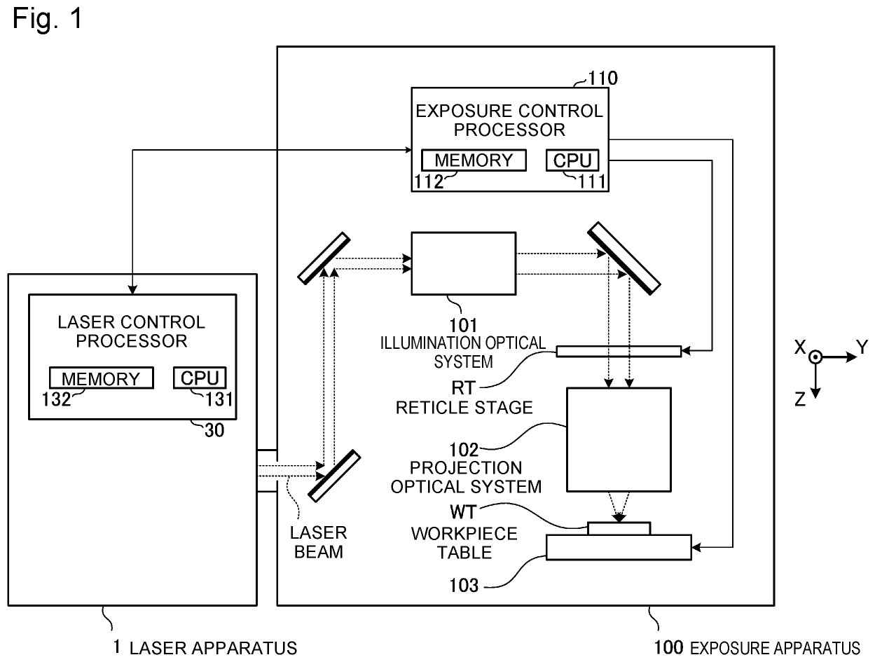

FIG. 1 schematically illustrates the configuration of an exposure system in a comparative example. The comparative example of the present disclosure is an example that the applicant recognizes as known only by the applicant, but is not a publicly known example that is recognized by the applicant.

The exposure system includes a laser apparatus 1 and an exposure apparatus 100. The laser apparatus 1 includes a laser control processor 30. The laser control processor 30 is a processing device including a memory 132 in which a control program is stored, and a central processing unit (CPU) 131 configured to execute the control program. The laser control processor 30 is specially configured or programmed to execute various kinds of processing included in the present disclosure. The laser apparatus 1 is configured to output a laser beam toward the exposure apparatus 100.

1.1 Configuration of Exposure Apparatus 100

The exposure apparatus 100 includes an illumination optical system 101, a projection optical system 102, and an exposure control processor 110.

The illumination optical system 101 illuminates the reticle pattern of a non-illustrated reticle disposed on a reticle stage RT with the laser beam incident from the laser apparatus 1.

The laser beam having transmitted through the reticle is imaged on a non-illustrated workpiece disposed on a workpiece table WT by reduced projection through the projection optical system 102. The workpiece is a photosensitive substrate such as a semiconductor wafer on which a resist film is applied, and can be moved by a stage 103.

The exposure control processor 110 is a processing device including a memory 112 in which a control program is stored, and a CPU 111 configured to execute the control program. The exposure control processor 110 is specially configured or programmed to execute various kinds of processing included in the present disclosure. The exposure control processor 110 collectively controls the exposure apparatus 100 and transmits and receives various kinds of data and various signals to and from the laser control processor 30.

1.2 Operation of Exposure Apparatus 100

The exposure control processor 110 transmits data of a wavelength target value, data of a pulse energy target value, and a trigger signal to the laser control processor 30. The laser control processor 30 controls the laser apparatus 1 in accordance with the data and the signal.

The exposure control processor 110 translates the reticle stage RT and the workpiece table WT in directions opposite to each other in synchronization. Accordingly, the workpiece is exposed to the laser beam reflecting the reticle pattern.

Through such an exposure process, the reticle pattern is transferred to the semiconductor wafer. Thereafter, an electronic device can be manufactured through a plurality of processes.

1.3 Configuration of Laser Apparatus 1

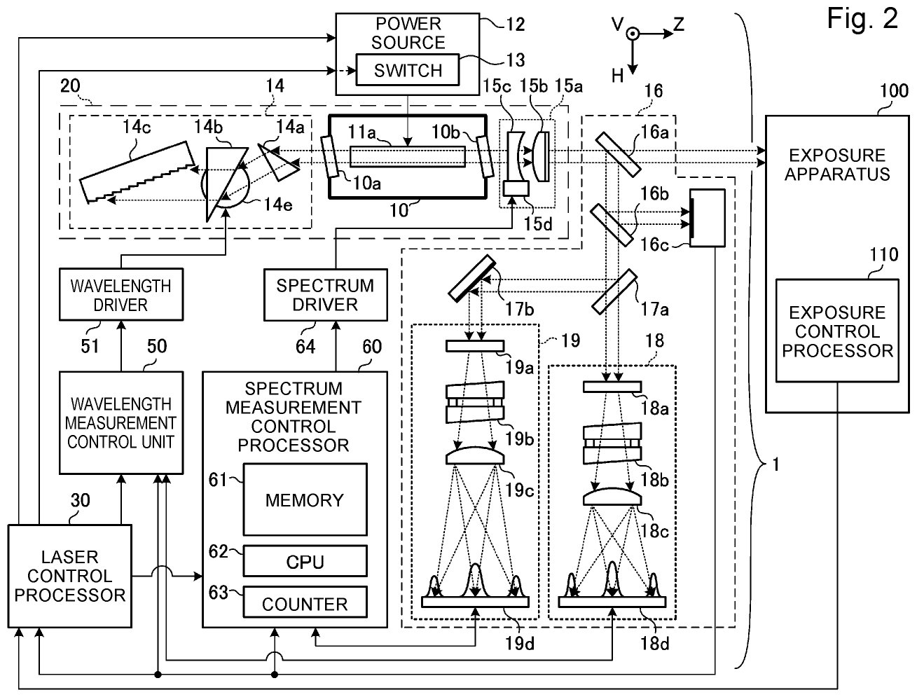

FIG. 2 schematically illustrates the configuration of the laser apparatus 1 according to the comparative example. The laser apparatus 1 includes a laser oscillator 20, a power source 12, a monitor module 16, the laser control processor 30, a wavelength measurement control unit 50, and a spectrum measurement control processor 60. The laser apparatus 1 is connectable to the exposure apparatus 100.

1.3.1 Laser Oscillator 20

The laser oscillator 20 includes a laser chamber 10, a discharge electrode 11a, a line narrowing module 14, and a spectrum waveform adjuster 15a.

The line narrowing module 14 and the spectrum waveform adjuster 15a constitute a laser resonator. The laser chamber 10 is disposed on the optical path of the laser resonator. Windows 10a and 10b are provided at respective ends of the laser chamber 10. The discharge electrode 11a and a non-illustrated discharge electrode paired with the discharge electrode 11a are disposed inside the laser chamber 10. The non-illustrated discharge electrode is disposed at a position overlapping the discharge electrode 11a in the direction of a V axis orthogonal to the sheet. Laser gas including, for example, argon gas or krypton gas as rare gas, fluorine gas as halogen gas, and neon gas as buffer gas is encapsulated in the laser chamber 10.

The power source 12 includes a switch 13 and is connected to the discharge electrode 11a and a non-illustrated charger.

The line narrowing module 14 includes a plurality of prisms 14a and 14b and a grating 14c. The prism 14b is supported by a rotation stage 14e. The rotation stage 14e is configured to rotate the prism 14b about an axis parallel to the V axis in accordance with a drive signal output from a wavelength driver 51. The selection wavelength of the line narrowing module 14 changes as the prism 14b is rotated.

The spectrum waveform adjuster 15a includes a cylindrical planoconvex lens 15b, a cylindrical planoconcave lens 15c, and a linear stage 15d. The cylindrical planoconcave lens 15c is positioned between the laser chamber 10 and the cylindrical planoconvex lens 15b.

The cylindrical planoconvex lens 15b and the cylindrical planoconcave lens 15c are disposed such that a convex surface of the cylindrical planoconvex lens 15b faces a concave surface of the cylindrical planoconcave lens 15c. The convex surface of the cylindrical planoconvex lens 15b and the concave surface of the cylindrical planoconcave lens 15c have focal axes parallel to the direction of the V axis. A flat surface positioned on a side opposite the convex surface of the cylindrical planoconvex lens 15b is coated with a partially reflective film.

1.3.2 Monitor Module 16

The monitor module 16 is disposed on the optical path of the laser beam between the spectrum waveform adjuster 15a and the exposure apparatus 100. The monitor module 16 includes beam splitters 16a, 16b, and 17a, an energy sensor 16c, a high reflectance mirror 17b, a wavelength detector 18, and a spectrometer 19.

The beam splitter 16a is positioned on the optical path of the laser beam output from the spectrum waveform adjuster 15a. The beam splitter 16a is configured to transmit part of the laser beam output from the spectrum waveform adjuster 15a toward the exposure apparatus 100 at high transmittance and to reflect the other part. The beam splitter 16b is positioned on the optical path of the laser beam reflected by the beam splitter 16a. The energy sensor 16c is positioned on the optical path of the laser beam reflected by the beam splitter 16b.

The beam splitter 17a is positioned on the optical path of the laser beam having transmitted through the beam splitter 16b. The high reflectance mirror 17b is positioned on the optical path of the laser beam reflected by the beam splitter 17a.

The wavelength detector 18 is disposed on the optical path of the laser beam having transmitted through the beam splitter 17a. The wavelength detector 18 includes a diffusion plate 18a, an etalon 18b, a light condensing lens 18c, and a line sensor 18d.

The diffusion plate 18a is positioned on the optical path of the laser beam having transmitted through the beam splitter 17a. The diffusion plate 18a has a large number of irregularities on its surface and is configured to transmit and diffuse the laser beam.

The etalon 18b is positioned on the optical path of the laser beam having transmitted through the diffusion plate 18a. The etalon 18b includes two partially reflective mirrors. The two partially reflective mirrors face each other across an air gap of a predetermined distance and are bonded to each other with a spacer interposed therebetween.

The light condensing lens 18c is positioned on the optical path of the laser beam having transmitted through the etalon 18b.

The line sensor 18d is positioned on the optical path of the laser beam having transmitted through the light condensing lens 18c and on the focal plane of the light condensing lens 18c. The line sensor 18d is a light distribution sensor including a large number of one-dimensionally arrayed light receiving elements. Alternatively, an image sensor including a large number of two-dimensionally arrayed light receiving elements may be used as a light distribution sensor in place of the line sensor 18d. The line sensor 18d may include a non-illustrated processor.

The line sensor 18d receives an interference fringe formed by the etalon 18b and the light condensing lens 18c. The interference fringe is an interference pattern of the laser beam and has a shape of concentric circles, and the square of the distance from the center of the concentric circles is proportional to a wavelength change. The non-illustrated processor may be configured to statistically process and to output data reflecting the interference pattern.

The spectrometer 19 is disposed on the optical path of the laser beam reflected by the high reflectance mirror 17b. The spectrometer 19 includes a diffusion plate 19a, an etalon 19b, a light condensing lens 19c, and a line sensor 19d. The line sensor 19d may include a non-illustrated processor. The configurations of these components are the same as those of the diffusion plate 18a, the etalon 18b, the light condensing lens 18c, and the line sensor 18d included in the wavelength detector 18, respectively. However, the etalon 19b has a free-spectral range smaller than that of the etalon 18b. Moreover, the light condensing lens 19c has a focal length longer than that of the light condensing lens 18c.

1.3.3 Various Kinds of Processing Devices

The spectrum measurement control processor 60 is a processing device including a memory 61 in which a control program is stored, a CPU 62 configured to execute the control program, and a counter 63. The spectrum measurement control processor 60 is specially configured or programmed to execute various kinds of processing included in the present disclosure.

The memory 61 also stores various kinds of data for calculating a spectrum line width. The various kinds of data include a device function S(λ) of the spectrometer 19. The counter 63 counts the number of pulses of the laser beam by counting the number of times of reception of an electric signal including pulse energy data output from the energy sensor 16c. Alternatively, the counter 63 may count the number of pulses of the laser beam by counting an oscillation trigger signal output from the laser control processor 30.

The wavelength measurement control unit 50 is a processing device including a non-illustrated memory in which a control program is stored, a non-illustrated CPU configured to execute the control program, and a non-illustrated counter. Similarly to the counter 63, the counter included in the wavelength measurement control unit 50 counts the number of pulses of the laser beam.

The laser control processor 30, the wavelength measurement control unit 50, and the spectrum measurement control processor 60 are described as separate constituent components in the present disclosure, but the laser control processor 30 may also serve as the wavelength measurement control unit 50 and the spectrum measurement control processor 60.

1.4 Operation

1.4.1 Laser Control Processor 30

The laser control processor 30 receives setting data of a target pulse energy and a target wavelength of the laser beam from the exposure control processor 110 included in the exposure apparatus 100.

The laser control processor 30 receives the trigger signal from the exposure control processor 110.

The laser control processor 30 transmits setting data of application voltage applied to the discharge electrode 11a to the power source 12 based on the target pulse energy. The laser control processor 30 transmits setting data of the target wavelength to the wavelength measurement control unit 50. The laser control processor 30 also transmits the oscillation trigger signal based on the trigger signal to the switch 13 included in the power source 12.

1.4.2 Laser Oscillator 20

When having received the oscillation trigger signal from the laser control processor 30, the switch 13 is turned on. When the switch 13 is turned on, the power source 12 generates high voltage in pulses from electric energy charged in the non-illustrated charger and applies the high voltage to the discharge electrode 11a.

When the high voltage is applied to the discharge electrode 11a, discharging occurs inside the laser chamber 10. A laser medium inside the laser chamber 10 is excited by energy of the discharging and transitions to a higher energy level. When transitioning to a lower energy level thereafter, the excited laser medium emits light of a wavelength in accordance with the difference between the energy levels.

The light generated inside the laser chamber 10 is output to the outside of the laser chamber 10 through the windows 10a and 10b. The beam width of the light output from the window 10a of the laser chamber 10 is expanded through the prisms 14a and 14b and the light is incident on the grating 14c.

The light incident on the grating 14c from the prisms 14a and 14b is reflected by a plurality of grooves of the grating 14c and is diffracted in a direction in accordance with the wavelength of the light.

The prisms 14a and 14b reduce the beam width of the diffracted light from the grating 14c and return the light to the laser chamber 10 through the window 10a.

The spectrum waveform adjuster 15a transmits and outputs part of the light output from the window 10b of the laser chamber 10 and reflects the other part back into the laser chamber 10 through the window 10b.

In this manner, light output from the laser chamber 10 reciprocates between the line narrowing module 14 and the spectrum waveform adjuster 15a and is amplified each time the light passes through a discharge space inside the laser chamber 10. The light is subjected to line narrowing each time the light is returned from the line narrowing module 14. In this manner, the light subjected to the laser oscillation and the line narrowing is output as a laser beam from the spectrum waveform adjuster 15a.

The linear stage 15d included in the spectrum waveform adjuster 15a moves the cylindrical planoconcave lens 15c along the optical path between the laser chamber 10 and the cylindrical planoconvex lens 15b in accordance with a drive signal output from a spectrum driver 64. Accordingly, the wavefront of light from the spectrum waveform adjuster 15a toward the line narrowing module 14 changes. The spectrum waveform and the spectrum line width of the laser beam change as the wavefront changes.

1.4.3 Monitor Module 16

The energy sensor 16c detects pulse energy of the laser beam and outputs data of the pulse energy to the laser control processor 30, the wavelength measurement control unit 50, and the spectrum measurement control processor 60. The data of the pulse energy is used by the laser control processor 30 to perform feedback control of the setting data of the application voltage applied to the discharge electrode 11a. In addition, the electric signal including the data of the pulse energy may be used by each of the wavelength measurement control unit 50 and the spectrum measurement control processor 60 to count the number of pulses.

The wavelength detector 18 generates waveform data of the interference fringe based on the amount of light at each light receiving element included in the line sensor 18d. The wavelength detector 18 may generate, as the waveform data of the interference fringe, a summed waveform obtained by summing the amounts of light at the respective light receiving elements. The wavelength detector 18 may generate the summed waveform a plurality of times and generate, as the waveform data of the interference fringe, an average waveform obtained by averaging a plurality of summed waveforms.

The wavelength detector 18 transmits the waveform data of the interference fringe to the wavelength measurement control unit 50 in accordance with a data output trigger output from the wavelength measurement control unit 50.

The spectrometer 19 generates a raw waveform reflecting the amounts of light at the respective light receiving elements included in the line sensor 19d having received the interference fringe. Alternatively, the spectrometer 19 generates a summed waveform Oi obtained by summing the raw waveform over Ni pulses. The spectrometer 19 generates the summed waveform Oi Na times and generates an average waveform Oa by averaging the Na summed waveforms Oi. The number Ni of summed pulses is, for example, five to eight, and the number Na of times of averaging is, for example, five to eight.

The spectrum measurement control processor 60 may count the number Ni of summed pulses and the number Na of times of averaging, and the spectrometer 19 may generate the summed waveform Oi and the average waveform Oa in accordance with a trigger signal output from the spectrum measurement control processor 60. The memory 61 of the spectrum measurement control processor 60 may store setting data of the number Ni of summed pulses and the number Na of times of averaging.

The spectrometer 19 extracts a partial waveform corresponding to the free-spectral range from the average waveform Oa. The extracted partial waveform represents the relation between the distance from the center of the concentric circles included in the interference fringe and light intensity. The spectrometer 19 acquires a measured spectrum waveform O(λ) by performing coordinate transform of the waveform into the relation between the wavelength and the light intensity. The coordinate transform of part of the average waveform Oa into the relation between the wavelength and the light intensity is also referred to as mapping to the spectral space. The measured spectrum waveform O(λ) corresponds to a measured waveform in the present disclosure.

The spectrometer 19 transmits the measured spectrum waveform O(λ) to the spectrum measurement control processor 60 in accordance with a data output trigger output from the spectrum measurement control processor 60.

Any or all of the processing of calculating the summed waveform Oi, the processing of calculating the average waveform Oa, and the processing of acquiring the measured spectrum waveform O(λ) by mapping to the spectral space may be performed by the spectrum measurement control processor 60 instead of the spectrometer 19. The processing of generating the average waveform Oa and the processing of acquiring the measured spectrum waveform O(λ) may be both performed by the spectrum measurement control processor 60 instead of the spectrometer 19.

1.4.4 Wavelength Measurement Control Unit 50

The wavelength measurement control unit 50 receives the setting data of the target wavelength from the laser control processor 30. In addition, the wavelength measurement control unit 50 calculates the central wavelength of the laser beam by using the waveform data of the interference fringe, which is output from the wavelength detector 18. The wavelength measurement control unit 50 performs feedback control of the central wavelength of the laser beam by outputting a control signal to the wavelength driver 51 based on the target wavelength and the calculated central wavelength.

1.4.5 Spectrum Measurement Control Processor 60

The spectrum measurement control processor 60 receives the measured spectrum waveform O(λ) from the spectrometer 19. Alternatively, the spectrum measurement control processor 60 may receive the raw waveform from the spectrometer 19, sum and average the raw waveform, and perform mapping to the spectral space, thereby acquiring the measured spectrum waveform O(λ). Alternatively, the spectrum measurement control processor 60 may receive the summed waveform Oi from the spectrometer 19 and perform mapping to the spectral space by averaging the summed waveform Oi, thereby acquiring the measured spectrum waveform O(λ). Alternatively, the spectrum measurement control processor 60 may receive the average waveform Oa from the spectrometer 19 and map the average waveform Oa to the spectral space, thereby acquiring the measured spectrum waveform O(λ).

The spectrum measurement control processor 60 calculates an estimated spectrum waveform I(λ) from the measured spectrum waveform O(λ) as described below.

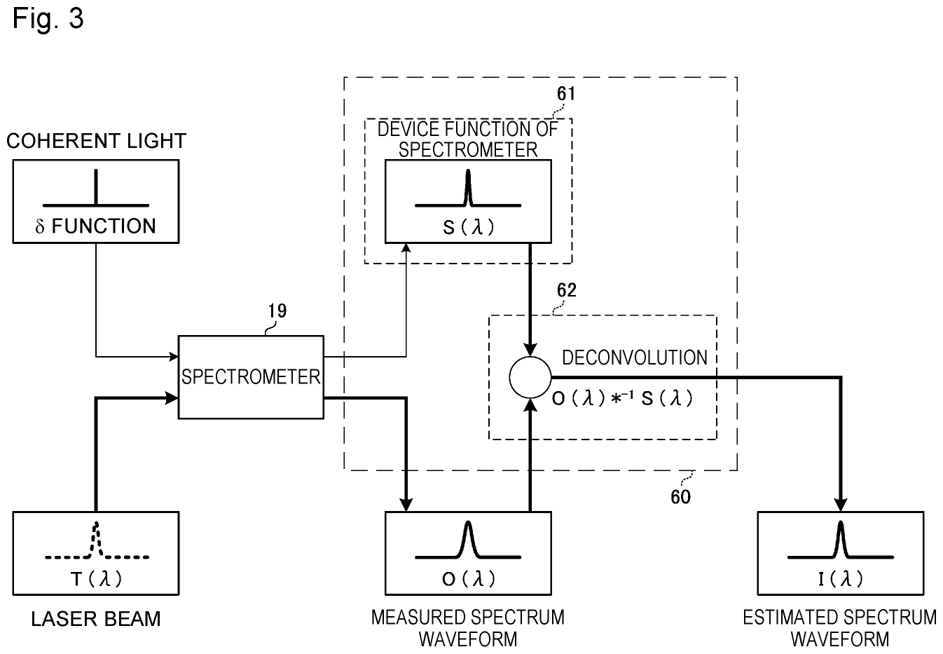

FIG. 3 is a block diagram for description of functions of the spectrum measurement control processor 60 in the comparative example.

The spectrometer 19 has a measurement characteristic unique to the device, and the measurement characteristic is expressed by the device function S(λ) as a function of a wavelength λ. The measured spectrum waveform O(λ) when a laser beam having an unknown spectrum waveform T(λ) is incident on the spectrometer 19 having the device function S(λ) and measured is expressed by the convolution of the unknown spectrum waveform T(λ) and the device function S(λ) as in Expression 1 below.

[Expression 1]

O(λ)=∫_{-∞}^{∞}T(x)·S(λ−x)dλ Expression 1

In other words, the convolution means the composition product of two functions.

The convolution can be expressed as described below by using the symbol *.

O(λ)=T(λ)*S(λ)

Fourier transform F(O(λ)) of the measured spectrum waveform O(λ) is equal to the product of Fourier transforms F(T(λ)) and F(S(λ)) of the two functions T(λ) and S(λ) each as described below.

F(O(λ))=F(T(λ))×F(S(λ))

This is called the convolution theorem.

The spectrum measurement control processor 60 holds, in the memory 61, the device function S(λ) of the spectrometer 19, which is measured in advance. To measure the device function S(λ), coherent light having a wavelength substantially equal to the central wavelength of a laser beam output from the laser apparatus 1 and having a narrow spectrum line width that can be substantially regarded as the 6 function is incident on the spectrometer 19. The spectrum waveform of the coherent light, which is measured by the spectrometer 19 can be set as the device function S(λ).

The CPU 62 included in the spectrum measurement control processor 60 performs deconvolution of the measured spectrum waveform O(λ) of the laser beam with the device function S(λ) of the spectrometer 19. The deconvolution means arithmetic processing of estimating an unknown function that satisfies a convolution expression. A waveform obtained through the deconvolution is set as the estimated spectrum waveform I(λ). The estimated spectrum waveform I(λ) represents an estimated relation between the wavelength of the unknown spectrum waveform T(λ) and the light intensity. The estimated spectrum waveform I(λ) is expressed as described below by using the symbol *⁻¹ that represents the deconvolution.

I(λ)=O(λ)*⁻¹S(λ)

The deconvolution can be calculated as described below in theory. First, an equation below is derived from the convolution theorem.

F(I(λ))=F(O(λ))/F(S(λ))

A calculation result of the deconvolution is obtained by performing inverse Fourier transform of both sides of the equation. Specifically, the estimated spectrum waveform I(λ) is expressed as described below with the symbol of F⁻¹ for inverse Fourier transform.

I(λ)=F⁻¹(F(O(λ))/F(S(λ)))

However, in actual numerical calculation, the deconvolution using Fourier transform and inverse Fourier transform is likely to be affected by a noise component included in measurement data. Thus, the deconvolution is preferably calculated by using an iterative method such as the Jacobi method or the Gauss-Seidel method, which can suppress the influence of the noise component.

1.5 Problem of Comparative Example

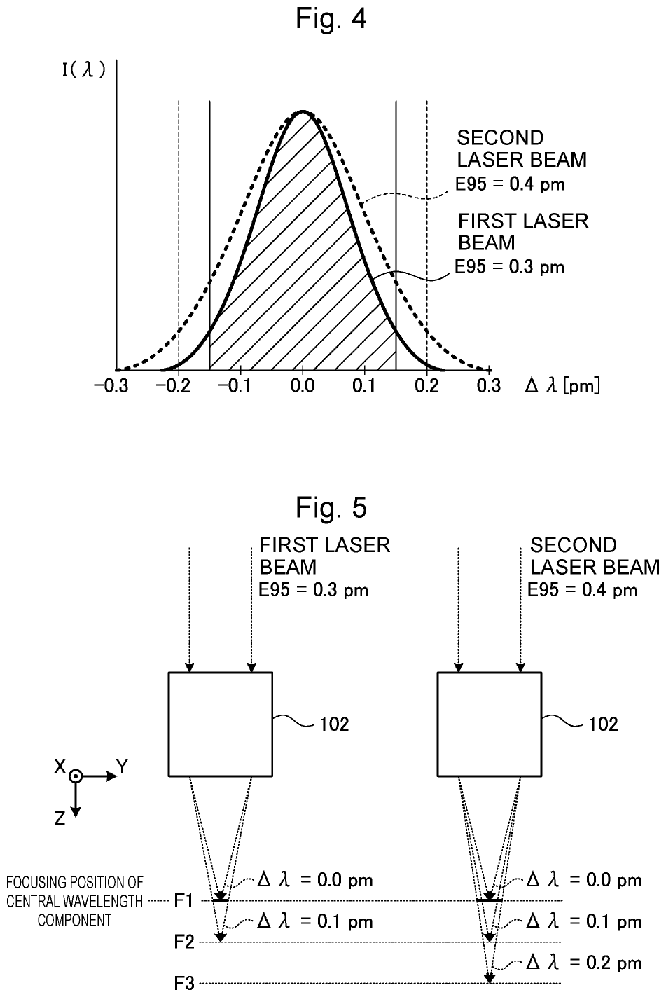

FIG. 4 is a graph illustrating an example of the estimated spectrum waveform I(λ) of a laser beam. The horizontal axis in FIG. 4 represents a wavelength deviation Δλ from the central wavelength. The estimated spectrum waveform I(λ) indicates light intensity for each wavelength component included in the wavelength band of the estimated spectrum waveform I(λ). A value obtained by integrating the estimated spectrum waveform I(λ) over a certain wavelength range is referred to as spectral energy in the wavelength range.

The full width of a part corresponding to 95% of spectral energy over the entire wavelength band of the estimated spectrum waveform I(λ) is referred to as a spectrum line width E95. In FIG. 4, the estimated spectrum waveform I(λ) of a first laser beam having a spectrum line width E95 of 0.3 pm is illustrated with a solid line, and the estimated spectrum waveform I(λ) of a second laser beam having a spectrum line width E95 of 0.4 pm is illustrated with a dashed line.

The angle of refraction at a lens surface differs in accordance with the wavelength of a laser beam, and thus difference in the spectrum waveform leads to difference in exposure performance of the exposure apparatus 100.

FIG. 5 schematically illustrates difference in focusing through the projection optical system 102 in accordance with the spectrum of a laser beam. FIG. 5 illustrates cases in which the first laser beam having a spectrum line width E95 of 0.3 pm and the second laser beam having a spectrum line width E95 of 0.4 pm, respectively, are incident on the projection optical system 102. The central wavelengths of the first and second laser beams are identical.

In the case in which the first laser beam is incident on the projection optical system 102, the focusing position of a central wavelength component as a peak wavelength is a first position F1 at a predetermined distance from the projection optical system 102. The focusing position of a wavelength component longer than the central wavelength by 0.1 pm is a second position F2 farther away from the projection optical system 102 than the first position F1. Imaging performance of the wavelength component at the first position F1 is lower than imaging performance of the central wavelength component.

In the case in which the second laser beam is incident on the projection optical system 102, the focusing position of the central wavelength component and the focusing position of the wavelength component longer than the central wavelength by 0.1 pm are the same as the first and second positions F1 and F2, respectively. However, the second laser beam includes a larger number of wavelength components longer than the central wavelength by 0.1 pm than the first laser beam. Imaging performance at the first position F1 degrades as the proportion of wavelength components different from the central wavelength increases.

The second laser beam also includes a wavelength component longer than the central wavelength by 0.2 pm. The focusing position of the wavelength component longer than the central wavelength by 0.2 pm is a third position F3 farther away from the projection optical system 102 than the second position F2. Imaging performance of the wavelength component at the first position F1 degrades as the wavelength difference from the central wavelength increases.

Thus, imaging performance is potentially different when the spectrum line width E95 is different although the focusing position of the central wavelength component is the same.

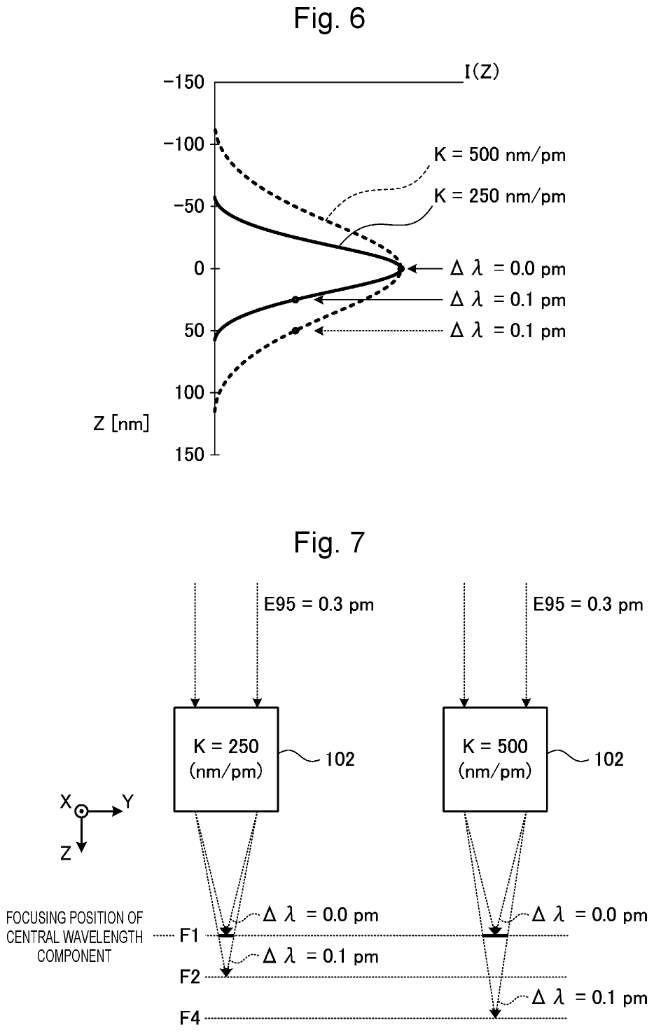

FIG. 6 is a graph illustrating distribution of the focusing position of a laser beam in the exposure apparatus 100. The vertical axis represents the focusing position on a Z axis illustrated in FIG. 1, and the horizontal axis represents the light intensity of a wavelength component focusing at the focusing position. The spectrum line width E95 of the laser beam is 0.3 pm. Distribution of the focusing position when a longitudinal chromatic aberration K of the projection optical system 102 of the exposure apparatus 100, in other words, difference in the focusing position per a wavelength difference of 1 pm is 250 nm/pm is illustrated with a solid line, and distribution of the focusing position when the longitudinal chromatic aberration K of the projection optical system 102 is 500 nm/pm is illustrated with a dashed line.

FIG. 7 schematically illustrates difference in focusing through the projection optical system 102 in accordance with the longitudinal chromatic aberration K. When the focusing position of the central wavelength component is fixed at the first position F1 irrespective of the longitudinal chromatic aberration K, the focusing position of the wavelength component longer than the central wavelength by 0.1 pm differs with the longitudinal chromatic aberration K. The focusing position of the wavelength component is the second position F2 separated from the focusing position of the central wavelength component by 25 nm when the longitudinal chromatic aberration K is 250 nm/pm. The focusing position of the wavelength component is a fourth position F4 separated from the focusing position of the central wavelength component by 50 nm when the longitudinal chromatic aberration K is 500 nm/pm.

In this manner, the focusing position of the wavelength component longer than the central wavelength by 0.1 pm differs with the longitudinal chromatic aberration K. Imaging performance of the wavelength component at the first position F1 degrades as the focusing position of the wavelength component is farther away from the first position F1.

Thus, imaging performance is potentially different when the longitudinal chromatic aberration K is different although the focusing position of the central wavelength component is the same.

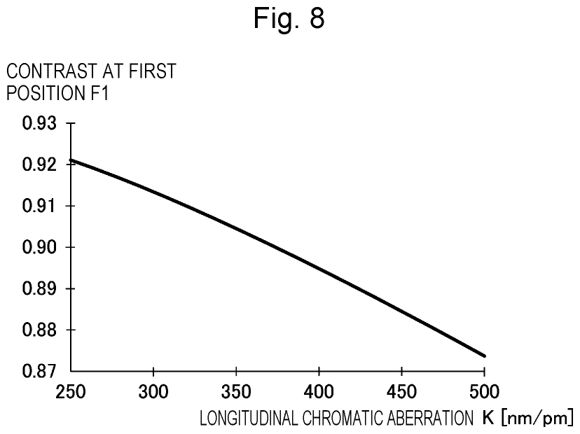

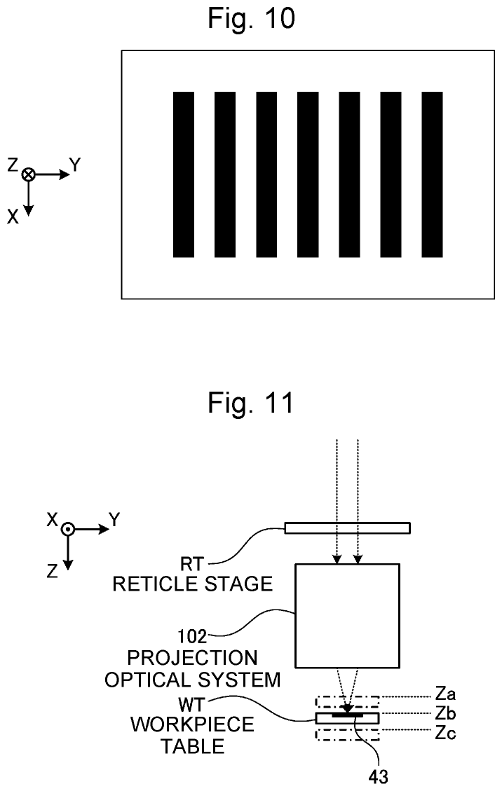

FIG. 8 is a graph illustrating the relation between the longitudinal chromatic aberration K and contrast at the first position F1 in a case of a constant spectrum waveform. FIG. 8 corresponds to a case in which a reticle pattern having a line-and-space shape with line and space widths of 100 nm is used. The reticle pattern having a line-and-space shape will be described later with reference to FIG. 10.

Even though the spectrum waveform is constant, contrast at the focusing position of the central wavelength component changes as the longitudinal chromatic aberration K of the projection optical system 102 changes, and thus imaging performance changes due to machine difference of the exposure apparatus 100 in some cases. Thus, imaging performance potentially cannot be sufficiently controlled by conventional spectrum control using the spectrum line width E95 as an indicator. Contrast will be described later.

In an embodiment described below, required exposure performance can be obtained by controlling the spectrum waveform in accordance with the longitudinal chromatic aberration K of the projection optical system 102.

### 2. Laser Apparatus 1a Configured to Control Spectrum Waveform in Accordance with Longitudinal Chromatic Aberration K

2.1 Configuration

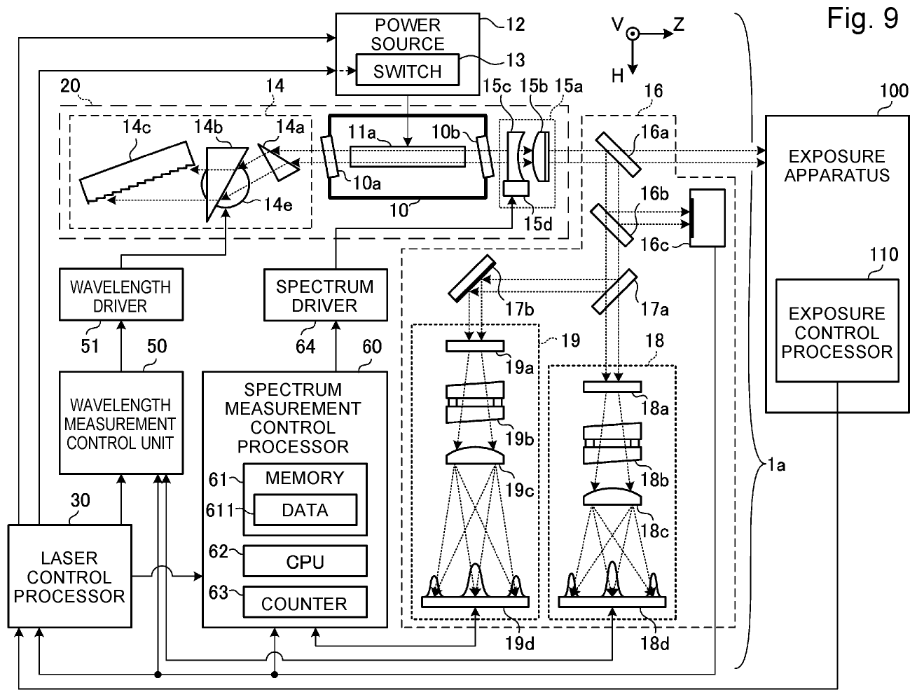

FIG. 9 schematically illustrates the configuration of a laser apparatus 1a according to an embodiment of the present disclosure.

In the laser apparatus 1a, the memory 61 included in the spectrum measurement control processor 60 stores data 611 in which the relation between the longitudinal chromatic aberration K and a spectrum evaluation value V is stored. The data 611 will be described later.

2.2 Measurement of Longitudinal Chromatic Aberration K

FIG. 10 illustrates an example of a reticle pattern used for measurement of the longitudinal chromatic aberration K.

A reticle pattern having a line-and-space shape in which transmission parts and non-transmission parts are alternately arranged as illustrated in FIG. 10 is disposed on the reticle stage RT (refer to FIG. 1) to measure the longitudinal chromatic aberration K of the projection optical system 102.

FIG. 11 schematically illustrates part of the exposure apparatus 100 according to the embodiment. A sensor 43 is disposed on the workpiece table WT to measure the longitudinal chromatic aberration K. Similarly to the line sensor 18d (refer to FIGS. 2 and 9), the sensor 43 may be a light distribution sensor including a large number of one-dimensionally arrayed light receiving elements or may be an image sensor including a large number of two-dimensionally arrayed light receiving elements.

The workpiece table WT can be moved in a direction parallel to the Z axis by the stage 103 (refer to FIG. 1). The position of a wafer surface can be moved to positions Za, Zb, and Zc illustrated in FIG. 11 by moving the workpiece table WT.

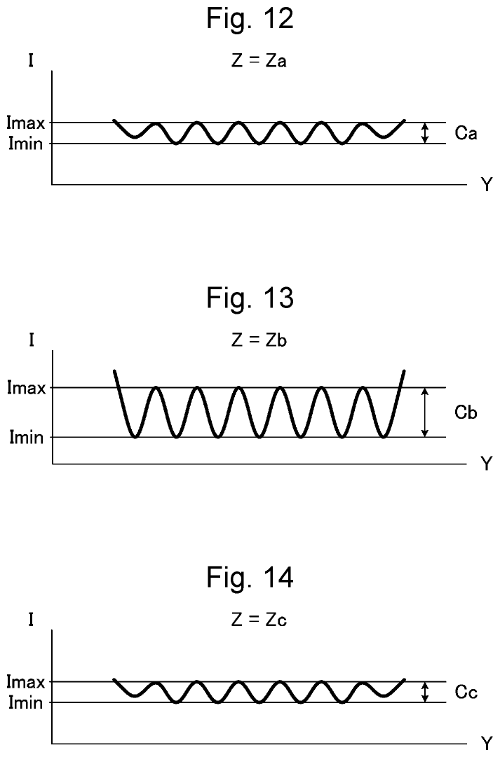

FIGS. 12 to 14 illustrate light intensity distribution measured by the sensor 43 when the wafer surface is moved to the positions Za to Zc, respectively. In FIGS. 12 to 14, the horizontal axis represents a position in a Y axial direction, and the vertical axis represents light intensity I at the position. Bright parts and dark parts alternately appear in the light intensity distribution illustrated in FIGS. 12 to 14 in accordance with the reticle pattern illustrated in FIG. 10. The lowest value Imin of the light intensity I is included in the light intensity at the dark parts. The highest value of the light intensity I among the bright parts sandwiched between the dark parts at both ends is Imax. Contrast is evaluated to be higher as the difference between the highest value Imax and the lowest value Imin is larger. Contrast may be defined as the difference between the highest value Imax and the lowest value Imin or may be defined as a value obtained by dividing the difference between the highest value Imax and the lowest value Imin by the sum of the highest value Imax and the lowest value Imin.

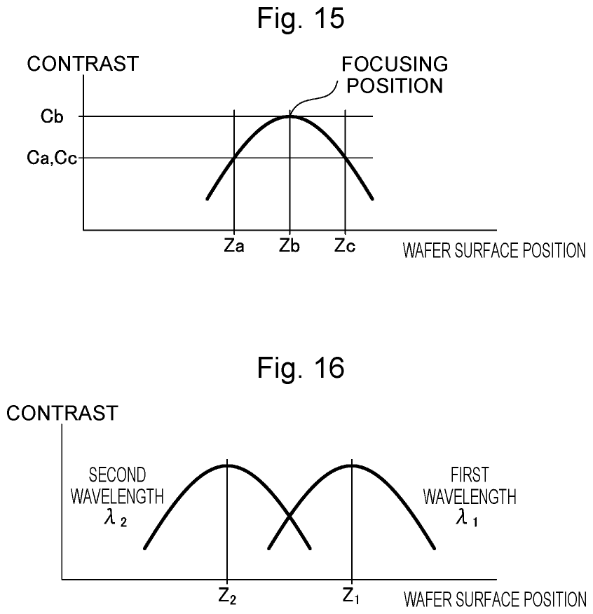

FIG. 15 is a graph illustrating an example of a result of contrast measurement performed while the workpiece table WT is moved in the direction parallel to the Z axis. As the workpiece table WT is moved, the position of the wafer surface changes and contrast changes in accordance with the position change. The focusing position is the position Zb in a case in which contrast is highest when the wafer surface is at the position Zb.

FIG. 16 is a graph illustrating the relation between the position of the wafer surface and contrast when two different wavelengths are used. A first focusing position when a first wavelength λ₁ is used is Z₁, and a second focusing position when a second wavelength λ₂ shorter than the first wavelength λ₁ is used is Z₂. In this case, the longitudinal chromatic aberration K can be defined by an equation below.

K=(Z₁−Z₂)/(λ₁−λ₂)

Specifically, the longitudinal chromatic aberration K is provided by the ratio of the difference “Z₁−Z₂” between the first and second focusing positions relative to the difference “λ₁−λ₂” between the first and second wavelengths.

2.3 Measurement of Spectrum Evaluation Value V

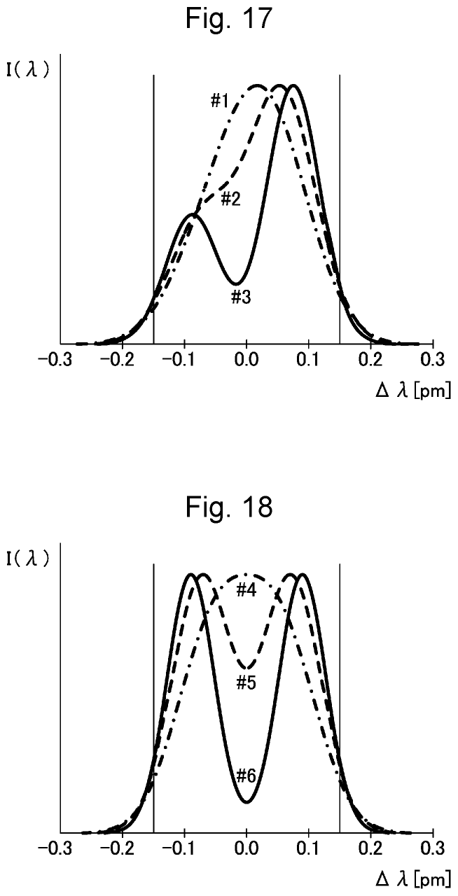

FIGS. 17 and 18 are graphs illustrating another example of the spectrum waveform of a laser beam. In each of FIGS. 17 and 18, the horizontal axis represents the wavelength deviation Δλ from the central wavelength. The spectrum line widths E95 of spectrum waveforms #1 to #3 illustrated in FIG. 17 and spectrum waveforms #4 to #6 illustrated in FIG. 18 are all 0.3 pm, but the shapes of the spectrum waveforms #1 to #6 are different from one another. The spectrum waveforms #1 to #3 have asymmetric spectrum distribution in which the peak wavelength is shifted to the longer wavelength side of the central wavelength, and the difference between the central wavelength and the peak wavelength is different among the spectrum waveforms #1 to #3. The central wavelength is, for example, the center of a wavelength width having a light intensity equal to or higher than 1/e² of peak intensity. The spectrum waveforms #4 to #6 have symmetric shapes, but the spectrum waveform #4 has a gentler curve near the peak than the spectrum waveform (refer to FIG. 4) in a Gaussian distribution shape. The spectrum waveforms #5 and #6 have spectrum distribution in which the peak wavelength is separated into two, and the difference between the central wavelength and the peak wavelength is different between the spectrum waveforms #5 and #6.

Imaging performance in the exposure apparatus 100 is evaluated by using the spectrum waveforms #1 to #6 as described below.

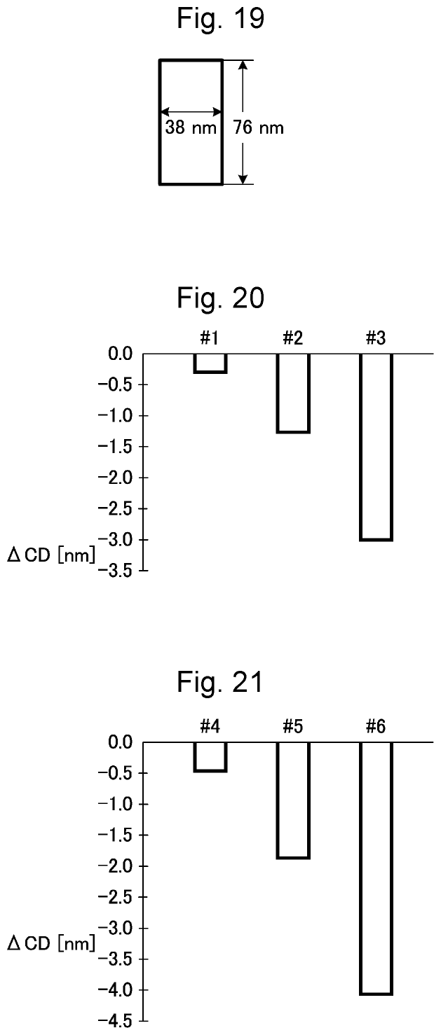

FIG. 19 illustrates a rectangular imaging pattern used for imaging performance evaluation. The mask used was designed such that a rectangular imaging pattern having a horizontal dimension of 38 nm and a vertical dimension of 76 nm is formed on the wafer surface through the projection optical system 102 when a spectrum waveform in a Gaussian distribution shape is used. The longitudinal chromatic aberration K of the projection optical system 102 was 250 nm/pm. When the spectrum waveforms #1 to #6 were used, a shift ΔCD from the vertical dimension of 76 nm when the exposure amount is adjusted such that the horizontal dimension of the imaging pattern on the wafer surface is 38 nm was calculated by simulation.

FIGS. 20 and 21 are graphs illustrating results of simulation of imaging performance in the exposure apparatus 100. FIG. 20 corresponds to cases in which the spectrum waveforms #1 to #3 illustrated in FIG. 17 were used, and FIG. 21 corresponds to cases in which the spectrum waveforms #4 to #6 illustrated in FIG. 18 were used.

As illustrated in FIG. 20, dimension error on the wafer surface tends to increase as the difference between the central wavelength and the peak wavelength increases and the asymmetry increases. Furthermore, as illustrated in FIG. 21, dimension error on the wafer surface tends to increase as the difference from the Gaussian distribution increases, despite the symmetric spectrum distribution.

In this manner, imaging performance in the exposure apparatus 100 is different in some cases even when the spectrum line width E95 is the same, and thus required exposure performance potentially cannot be obtained only by setting the spectrum line width E95 to a target value. For this reason, the spectrum evaluation value V based on consideration of the shape of the spectrum waveform is defined as described below.

First, a barycenter wavelength λc of the estimated spectrum waveform I(λ) is defined by Expression 2 below.

$$\begin{matrix}[ Expression 2 ] & \\ λc = \frac{\int I ( λ ) λ d λ}{\int I ( λ ) d λ} & Expression 2\end{matrix}$$

The numerator of Expression 2 is a value obtained by integrating the product of the light intensity represented by the estimated spectrum waveform I(λ) and the wavelength λ with respect to the wavelength band of the estimated spectrum waveform I(λ). The denominator of Expression 2 is a value obtained by integrating the light intensity represented by the estimated spectrum waveform I(λ) with respect to the wavelength band of the estimated spectrum waveform I(λ). The barycenter wavelength λc is an example of a representative wavelength in the present disclosure.

The spectrum evaluation value V of the estimated spectrum waveform I(λ) is defined by Expression 3 below.

$$\begin{matrix}[ Expression 3 ] & \\ V = \frac{\int I ( λ ) {( λ - λ c )}^{2} d λ}{λ s \int I ( λ ) d λ} & Expression 3\end{matrix}$$

The numerator of Expression 3 is a value obtained by integrating the product of the light intensity represented by the estimated spectrum waveform I(λ) and the function “(λ−λc)²” of wavelength deviation from the barycenter wavelength λc with respect to the wavelength band of the estimated spectrum waveform I(λ). The spectrum evaluation value V corresponds to an evaluation value in the present disclosure.

The denominator of Expression 3 is the product of a constant λs and a value obtained by integrating the light intensity represented by the estimated spectrum waveform I(λ) with respect to the wavelength band of the estimated spectrum waveform I(λ). The constant λs may be any of (1) to (4) below.
(1) 1
(2) The barycenter wavelength λc
(3) The spectrum line width E95 of the estimated spectrum waveform I(λ)
(4) The standard deviation of a spectrum waveform having a Gaussian distribution shape and having the same spectrum line width E95 as the estimated spectrum waveform I(λ)

The spectrum evaluation value V is in the order of the square of the wavelength λ when the constant λs is one as described above in (1), but the spectrum evaluation value V in the order of the wavelength λ can be obtained through division by the constant λs obtained from a function of the wavelength λ as described above in (2) to (4).

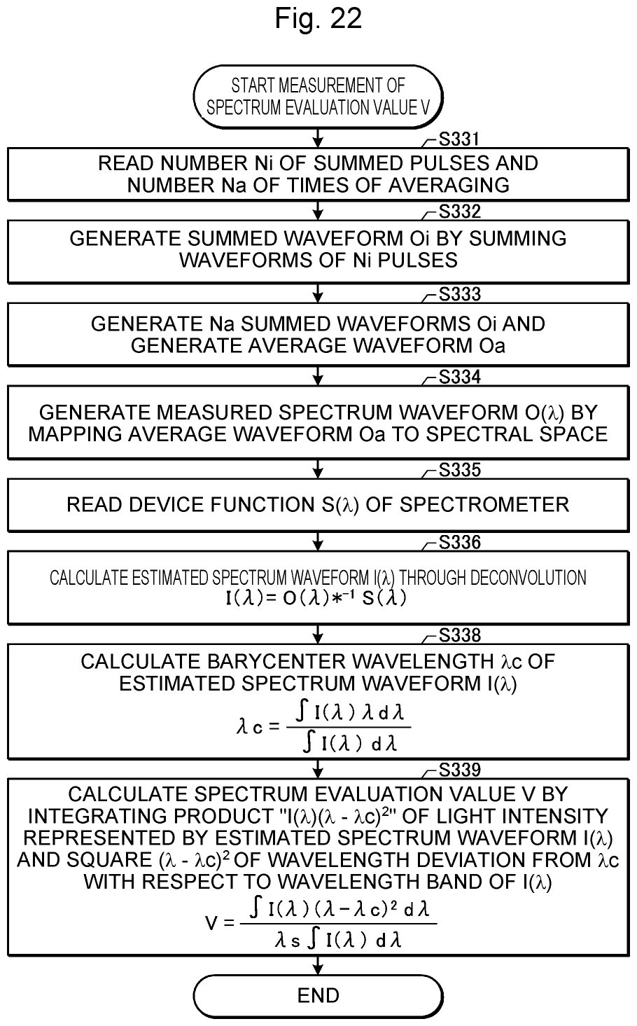

FIG. 22 is a flowchart illustrating the process of measurement of the spectrum evaluation value V in the embodiment.

The spectrum measurement control processor 60 generates the summed waveform Oi and the average waveform Oa based on the interference pattern of a laser beam and calculates the estimated spectrum waveform I(λ) and the spectrum evaluation value V as described below.

At S331, the spectrum measurement control processor 60 reads the number Ni of summed pulses and the number Na of times of averaging from the memory 61.

At S332, the spectrum measurement control processor 60 receives the raw waveform reflecting the amount of light at each light receiving element included in the line sensor 19d and generates the summed waveform Oi by summing the raw waveform over Ni pulses.

At S333, the spectrum measurement control processor 60 generates the summed waveform Oi Na times and generates the average waveform Oa by averaging the Na summed waveforms Oi.

At S334, the spectrum measurement control processor 60 generates the measured spectrum waveform O(λ) by mapping the average waveform Oa to the spectral space.

At S335, the spectrum measurement control processor 60 reads the device function S(λ) of the spectrometer 19 from the memory 61.

At S336, the spectrum measurement control processor 60 calculates the estimated spectrum waveform I(λ) through deconvolution of the measured spectrum waveform O(λ) with the device function S(λ).

At S338, the spectrum measurement control processor 60 calculates the barycenter wavelength λc of the estimated spectrum waveform I(λ) by Expression 2.

At S339, the spectrum measurement control processor 60 calculates the spectrum evaluation value V of the estimated spectrum waveform I(λ) by Expression 3.

After S339, the spectrum measurement control processor 60 ends processing of the present flowchart.

2.4 Comparison Between Spectrum Evaluation Value V and Spectrum Line Width E95

Usefulness of the spectrum evaluation value V and an evaluation method using the spectrum evaluation value V will be described below in comparison with the spectrum line width E95. As described below, the spectrum evaluation value V is applicable to various shapes of an imaging pattern.

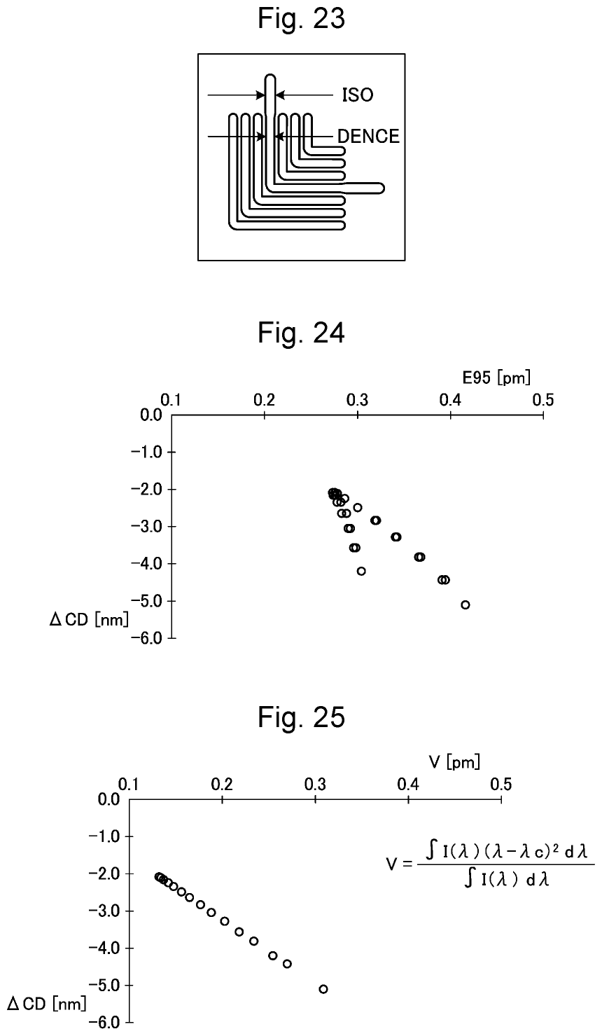

FIG. 23 illustrates an imaging pattern used for usefulness comparison between the spectrum evaluation value V and the spectrum line width E95. The imaging pattern illustrated in FIG. 23 includes two kinds of patterns, namely, a DENCE pattern in which a plurality of exposure regions are densely spaced and an ISO pattern at a position isolated from the other exposure regions. A shift of the ISO pattern from a reference dimension when the exposure amount is adjusted such that the DENCE pattern has a dimension of 45 nm is represented by ΔCD. The reference dimension of the ISO pattern is the dimension of the ISO pattern when the spectrum line width E95 is 0.01 pm.

FIG. 24 is a graph illustrating the relation between the spectrum line width E95 and ΔCD in the imaging pattern in FIG. 23, and FIG. 25 is a graph illustrating the relation between the spectrum evaluation value V and ΔCD in the imaging pattern in FIG. 23. For each of FIGS. 24 and 25, ΔCD was plotted by performing simulation by using a large number of variations including the spectrum waveforms exemplarily illustrated in FIGS. 17 and 18.

In FIG. 24, two tendencies are observed for the rate of change of ΔCD with change of the spectrum line width E95. Thus, imaging performance on the wafer surface cannot be accurately determined by measuring the spectrum line width E95 in some cases.

In FIG. 25, the relation between the spectrum evaluation value V and ΔCD is represented by substantially one straight line. Thus, imaging performance on the wafer surface can be determined by measuring the spectrum evaluation value V. Required imaging performance can be achieved by controlling the spectrum evaluation value V to a certain target value.

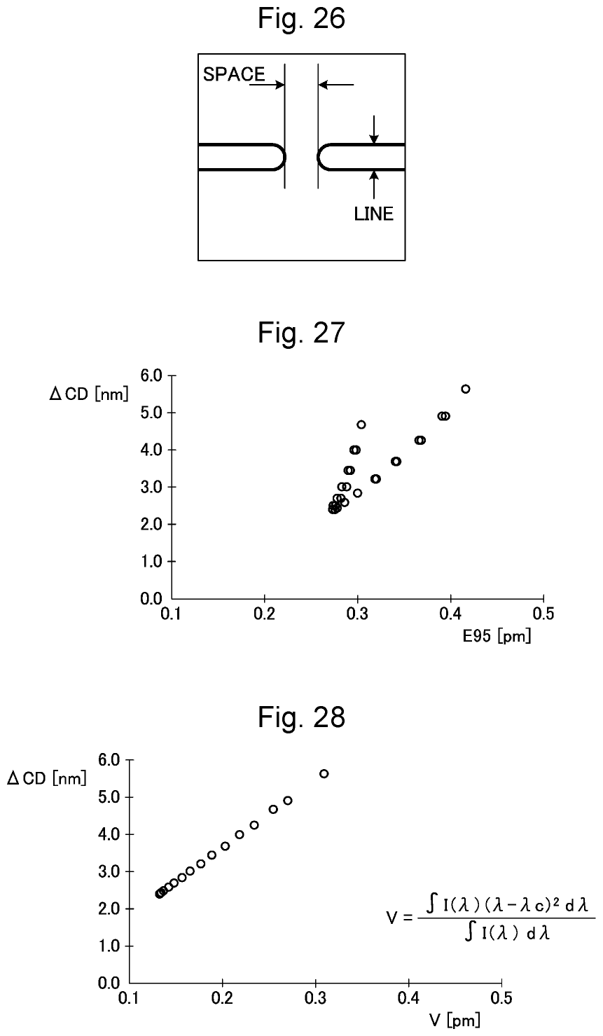

FIG. 26 illustrates another imaging pattern used for usefulness comparison between the spectrum evaluation value V and the spectrum line width E95. The imaging pattern illustrated in FIG. 26 includes two kinds of patterns, namely, a LINE pattern representing a wire and a SPACE pattern representing a gap to an adjacent wire. A shift of the SPACE pattern from a reference dimension when the exposure amount is adjusted such that the LINE pattern has a dimension of 100 nm is represented by ΔCD.

FIG. 27 is a graph illustrating the relation between the spectrum line width E95 and ΔCD in the imaging pattern in FIG. 26, and FIG. 28 is a graph illustrating the relation between the spectrum evaluation value V and ΔCD in the imaging pattern in FIG. 26. For each of FIGS. 27 and 28, ΔCD was plotted by performing simulation by using a large number of variations including the spectrum waveforms exemplarily illustrated in FIGS. 17 and 18.

In FIG. 27, two tendencies are observed for the rate of change of ΔCD with change of the spectrum line width E95. Thus, imaging performance on the wafer surface cannot be accurately determined by measuring the spectrum line width E95 in some cases.

In FIG. 28, the relation between the spectrum evaluation value V and ΔCD is represented by substantially one straight line. Thus, imaging performance on the wafer surface can be determined by measuring the spectrum evaluation value V. Required imaging performance can be achieved by controlling the spectrum evaluation value V to a certain target value.

2.5 Modification of Spectrum Evaluation Value V

Although the square “(λ−λc)²” of wavelength deviation “λ−λc” from the barycenter wavelength λc is used in Expression 3, the present disclosure is not limited thereto. The spectrum evaluation value V may be calculated by Expression 4 below.

$$\begin{matrix}[ Expression 4 ] & \\ V = \frac{\int I ( λ ) {\vert λ - λ c \vert}^{N} d λ}{\int I ( λ ) d λ} & Expression 4\end{matrix}$$

Expression 4 is different from Expression 3 in that the absolute value of the wavelength deviation “λ−λc” is raised to the power of N instead of squaring the wavelength deviation “λ−λc” in Expression 3. The power index N is a positive number. Expression 4 when the value of the power index N is set to two is equivalent to Expression 3 when λs is set to one.

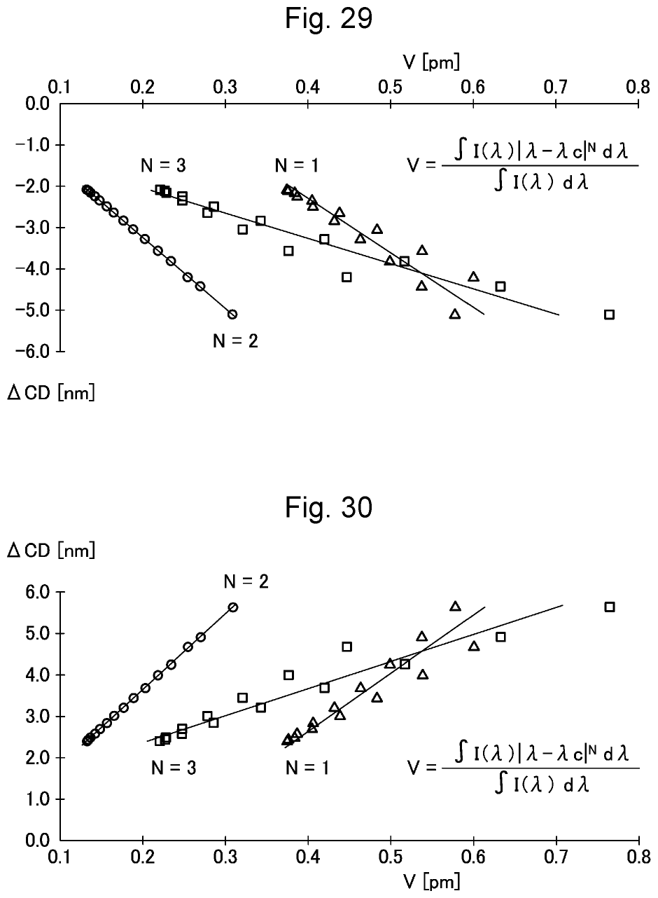

FIG. 29 is a graph illustrating the relation between the spectrum evaluation value V of Expression 4 and ΔCD in the imaging pattern in FIG. 23. FIG. 30 is a graph illustrating the relation between the spectrum evaluation value V of Expression 4 and ΔCD in the imaging pattern in FIG. 26. In FIGS. 29 and 30, simulation results in cases in which the value of the power index N in Expression 4 is set to one, two, and three are illustrated together with their regression lines. Correlation between the spectrum evaluation value V and ΔCD is observed in any of the cases in which the value of the power index N is set to one, two, and three. Imaging performance on the wafer surface can be determined by measuring such a spectrum evaluation value V.

In any of FIGS. 29 and 30, a determination coefficient indicating the degree of fitting of each regression line is highest in the case in which the value of the power index N is two. The value of the power index N is preferably set to 1.9 to 2.1.

2.6 Control of Spectrum Evaluation Value V in Accordance with Longitudinal Chromatic Aberration K

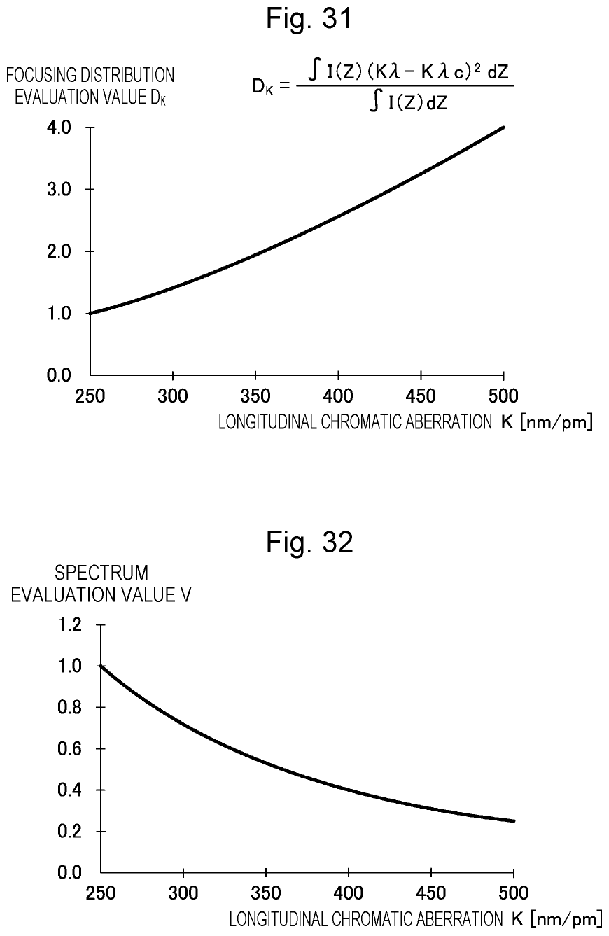

FIG. 31 is a graph illustrating the relation between the longitudinal chromatic aberration K and a focusing distribution evaluation value D_{K} when the spectrum waveform is fixed without change. The focusing distribution evaluation value Dx is an evaluation value that enables evaluation of imaging performance by adding the longitudinal chromatic aberration K to the spectrum evaluation value V, and is calculated by Expression 5 below.

$$\begin{matrix}[ Expression 5 ] & \\ {D}_{K} = \frac{\int I ( Z ) {( K λ - K λ c )}^{2} dZ}{\int I ( Z ) dZ} & Expression 5\end{matrix}$$

Expression 5 is equivalent to Expression 3 in which the wavelength λ is replaced with a product Kλ of the longitudinal chromatic aberration K and the wavelength λ and the constant λs is set to one. When the spectrum waveform is fixed without change, the focusing distribution evaluation value D_{K} is substantially proportional to the square of the longitudinal chromatic aberration K. This indicates that the shift ΔCD from the reference dimension increases as the focusing distribution evaluation value D_{K} increases.

In the embodiment, the spectrum evaluation value V is controlled so that the focusing distribution evaluation value D_{K} is kept constant irrespective of the longitudinal chromatic aberration K.

FIG. 32 is a graph illustrating the relation set in the embodiment between the longitudinal chromatic aberration K and the spectrum evaluation value V. The relation between the longitudinal chromatic aberration K and the spectrum evaluation value V is set so that the focusing distribution evaluation value D_{K} is kept constant irrespective of the longitudinal chromatic aberration K. As a result, the relation between the longitudinal chromatic aberration K and the spectrum evaluation value V illustrated in FIG. 32 is such that the spectrum evaluation value V is substantially inversely proportional to the square of the longitudinal chromatic aberration K. The memory 61 included in the spectrum measurement control processor 60 may store a relational expression of the longitudinal chromatic aberration K and the spectrum evaluation value V as the data 611 in which the relation between the longitudinal chromatic aberration K and the spectrum evaluation value V is stored.

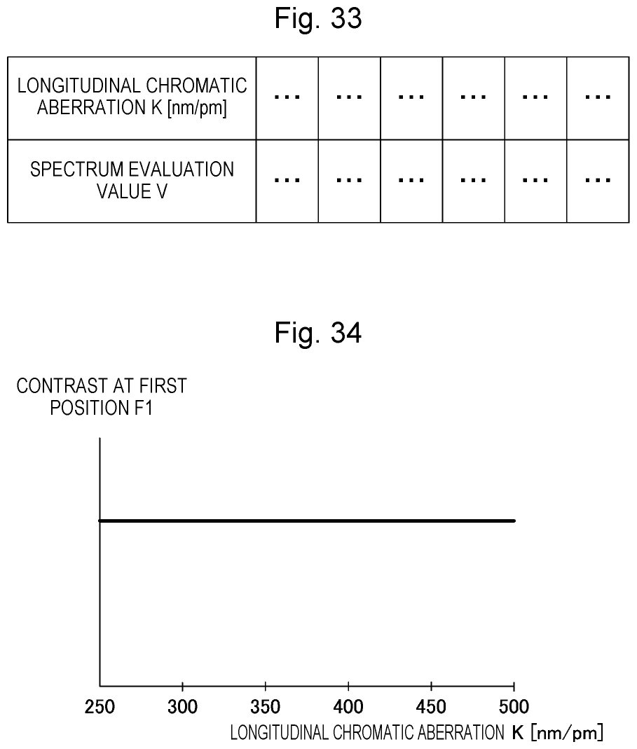

FIG. 33 illustrates a table representing the relation set in the embodiment between the longitudinal chromatic aberration K and the spectrum evaluation value V. The relation between the longitudinal chromatic aberration K and the spectrum evaluation value V is set so that the focusing distribution evaluation value D_{K} is kept constant irrespective of the longitudinal chromatic aberration K. The memory 61 included in the spectrum measurement control processor 60 may store a table associating the longitudinal chromatic aberration K and the spectrum evaluation value V as the data 611 in which the relation between the longitudinal chromatic aberration K and the spectrum evaluation value V is stored.

FIG. 34 is a graph illustrating the relation between the longitudinal chromatic aberration K and contrast at the focusing position when the spectrum evaluation value V is set so that the focusing distribution evaluation value D_{K} is kept constant. Since the spectrum evaluation value V is set so that the focusing distribution evaluation value D_{K} is kept constant by using the relation illustrated in FIG. 32 or FIG. 33, contrast at the focusing position is kept substantially constant irrespective of the longitudinal chromatic aberration K. In other words, when the spectrum evaluation value V is controlled so that the focusing distribution evaluation value D_{K} is kept constant, change of contrast in accordance with change of the longitudinal chromatic aberration K is smaller than when the spectrum evaluation value V is fixed. Since the spectrum evaluation value V is set so that the focusing distribution evaluation value D_{K} is kept constant, exposure performance can be stabilized irrespective of machine difference of the exposure apparatus 100.

Although Expression 5 is equivalent to Expression 3 in which the wavelength λ is replaced with the product Kλ of the longitudinal chromatic aberration K and the wavelength λ, the present disclosure is not limited thereto. The wavelength λ in Expression 4 may be replaced with the product Kλ. In this case, the focusing distribution evaluation value D_{K} when the spectrum waveform is fixed without change is substantially proportional to the N-th power of the longitudinal chromatic aberration K. When the spectrum evaluation value V is set so that the focusing distribution evaluation value D_{K} is kept constant irrespective of the longitudinal chromatic aberration K, the spectrum evaluation value V is substantially inversely proportional to the N-th power of the longitudinal chromatic aberration K.

2.7 Generation of Table

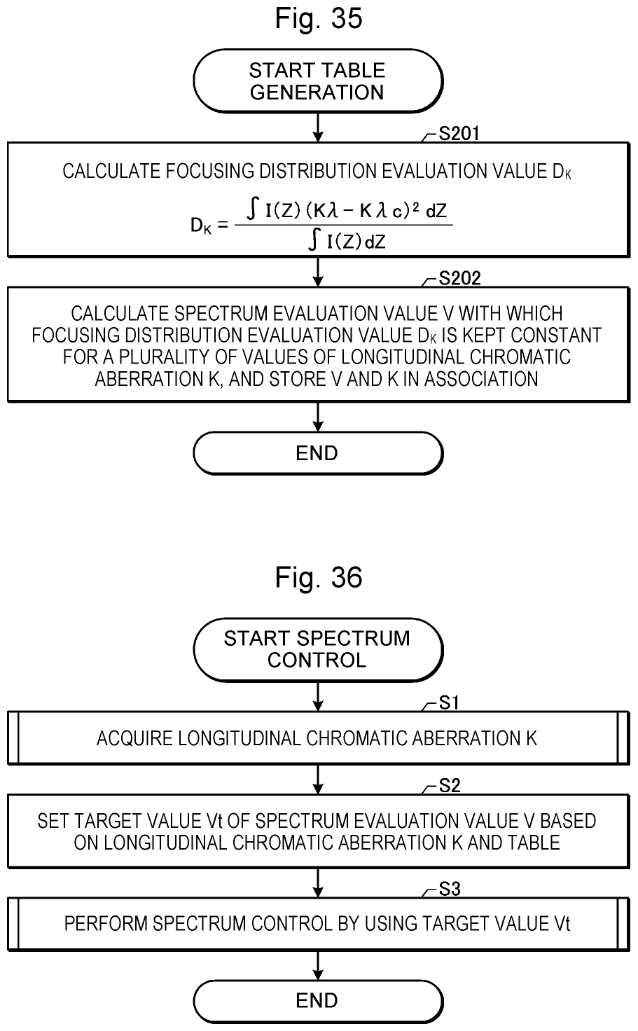

FIG. 35 is a flowchart illustrating the process of table generation in the embodiment. The spectrum measurement control processor 60 generates a table representing the relation between the longitudinal chromatic aberration K and the spectrum evaluation value V as described below.

At S201, the spectrum measurement control processor 60 calculates the focusing distribution evaluation value D_{K} by Expression 5.

At S202, the spectrum measurement control processor 60 calculates the spectrum evaluation value V with which the focusing distribution evaluation value D_{K} is kept constant for a plurality of values of the longitudinal chromatic aberration K, and stores the spectrum evaluation value V and the longitudinal chromatic aberration K in association with each other in the memory 61.

After S202, the spectrum measurement control processor 60 ends processing of the present flowchart.

2.8 Operation of Spectrum Control

FIG. 36 is a flowchart illustrating the process of spectrum control in the embodiment. The spectrum control illustrated in FIG. 36 may be performed by the exposure control processor 110 or may be performed by the laser control processor 30 or the spectrum measurement control processor 60. The exposure control processor 110, the laser control processor 30, and the spectrum measurement control processor 60 each correspond to a processor in the present disclosure. These processors are collectively referred to as a “processor” in description of FIG. 36. The processor controls the spectrum waveform adjuster 15a by setting a target value Vt of the spectrum evaluation value V by using the longitudinal chromatic aberration K as described below.

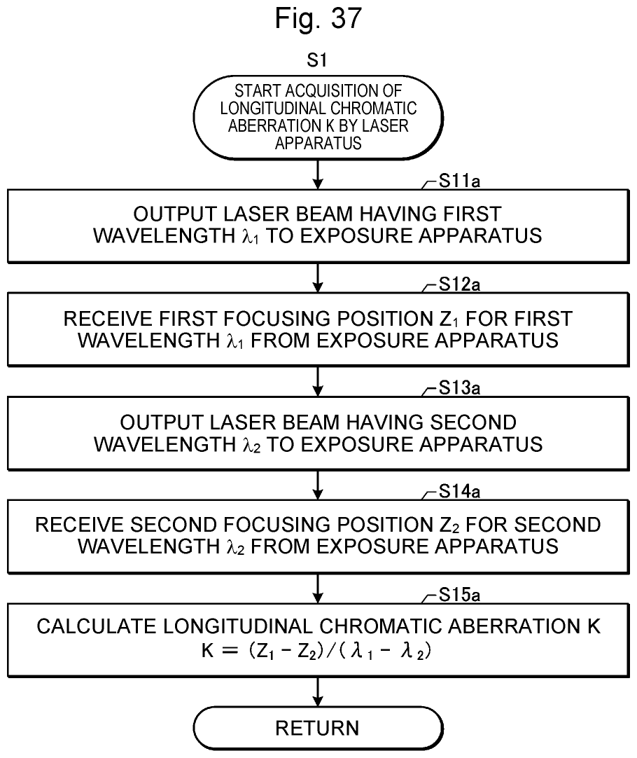

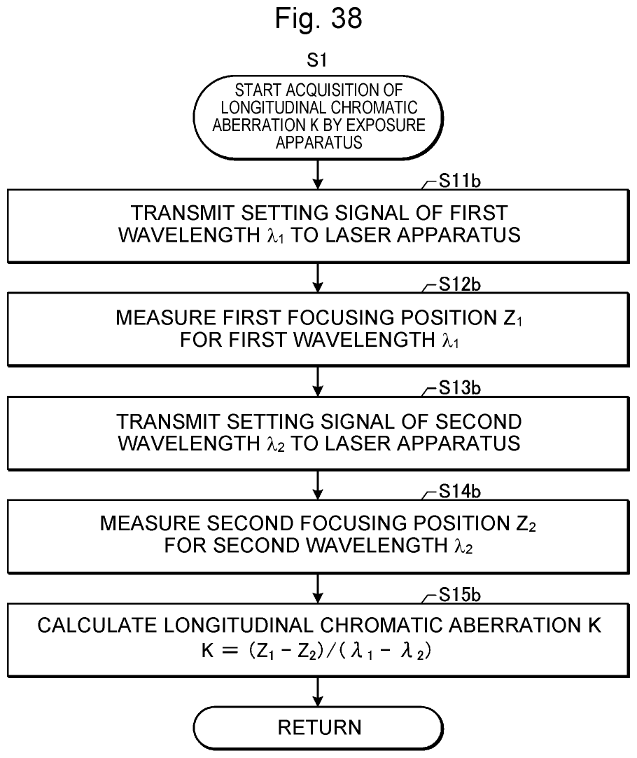

At S1, the processor acquires the longitudinal chromatic aberration K of the projection optical system 102 of the exposure apparatus 100. Details of S1 will be described later with reference to FIGS. 37 and 38.

At S2, the processor refers to the data 611 in which the relation between the longitudinal chromatic aberration K and the spectrum evaluation value V is stored, and sets the target value Vt of the spectrum evaluation value V based on the longitudinal chromatic aberration K. The data 611 may be the relational expression described above with reference to FIG. 32 or may be the table described above with reference to FIGS. 33 and 35.

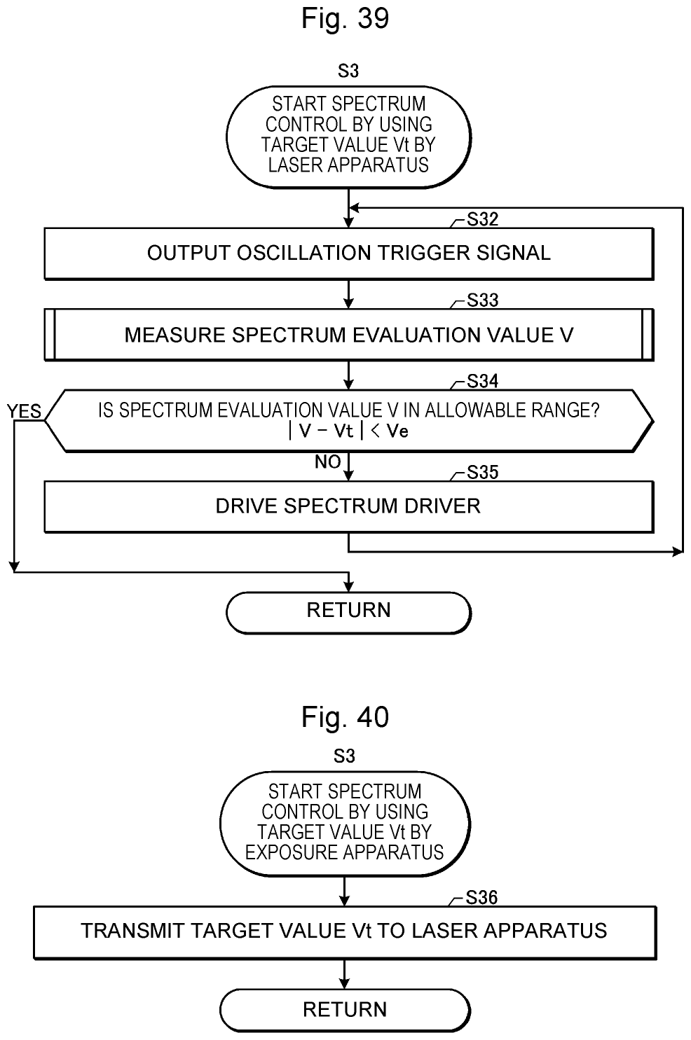

At S3, the processor performs spectrum control by using the target value Vt. Details of S3 will be described later with reference to FIGS. 39 and 40.

After S3, the processor ends processing of the present flowchart.

2.8.1 Acquisition of Longitudinal Chromatic Aberration K by Laser Apparatus 1a

FIG. 37 is a flowchart illustrating processing that the laser apparatus 1a acquires the longitudinal chromatic aberration K. The processing illustrated in FIG. 37 corresponds to a first exemplary subroutine of S1 in FIG. 36.

At S11a, the laser control processor 30 controls the laser oscillator 20 to output a laser beam having the first wavelength λ₁ to the exposure apparatus 100.

At S12a, the laser control processor 30 receives, from the exposure apparatus 100, the first focusing position Z₁ measured by the exposure apparatus 100 by using the laser beam having the first wavelength λ₁.

At S13a, the laser control processor 30 controls the laser oscillator 20 to output a laser beam having the second wavelength λ₂ shorter than the first wavelength λ₁ to the exposure apparatus 100.

At S14a, the laser control processor 30 receives, from the exposure apparatus 100, the second focusing position Z₂ measured by the exposure apparatus 100 by using the laser beam having the second wavelength λ₂.

At S15a, the laser control processor 30 calculates the longitudinal chromatic aberration K based on the first and second wavelengths λ₁ and λ₂ and the first and second focusing positions Z₁ and Z₂.

After S15a, the laser control processor 30 ends processing of the present flowchart and returns to the processing illustrated in FIG. 36.

2.8.2 Acquisition of Longitudinal Chromatic Aberration K by Exposure Apparatus 100

FIG. 38 is a flowchart illustrating processing that the exposure apparatus 100 acquires the longitudinal chromatic aberration K. The processing illustrated in FIG. 38 corresponds to a second exemplary subroutine of S1 in FIG. 36.

At S11b, the exposure control processor 110 transmits a setting signal of the first wavelength λ₁ to the laser apparatus 1a.

At S12b, the exposure control processor 110 measures the first focusing position Z₁ by using a laser beam having the first wavelength λ₁.

At S13b, the exposure control processor 110 transmits a setting signal of the second wavelength λ₂ shorter than the first wavelength λ₁ to the laser apparatus 1a.

At S14b, the exposure control processor 110 measures the second focusing position Z₂ by using a laser beam having the second wavelength λ₂.

At S15b, the exposure control processor 110 calculates the longitudinal chromatic aberration K based on the first and second wavelengths λ₁ and λ₂ and the first and second focusing positions Z₁ and Z₂.

After S15b, the exposure control processor 110 ends processing of the present flowchart and returns to the processing illustrated in FIG. 36.

2.8.3 Spectrum Control Using Target Value Vt by Laser Apparatus 1a

FIG. 39 is a flowchart illustrating processing that the laser apparatus 1a performs spectrum control by using the target value Vt. The processing illustrated in FIG. 39 corresponds to a first exemplary subroutine of S3 in FIG. 36.

At S32, the laser control processor 30 outputs an oscillation trigger signal. When the oscillation trigger signal is output, a laser beam is output from the laser oscillator 20.

At S33, the laser control processor 30 measures the spectrum evaluation value V by using the laser beam output from the laser oscillator 20. The processing at S33 is performed by the spectrum measurement control processor 60 in the procedure described above with reference to FIG. 22.

At S34, the laser control processor 30 compares the spectrum evaluation value V with the target value Vt and determines whether the spectrum evaluation value V is in an allowable range.

For example, it is determined whether the absolute value of the difference between the spectrum evaluation value V and the target value Vt is smaller than an allowable error Ve. The target value Vt used here is the target value Vt set by the laser control processor 30, the spectrum measurement control processor 60, or the exposure control processor 110 at S2 in FIG. 36.

When the spectrum evaluation value V is not in the allowable range at S34 (NO at S34), the laser control processor 30 advances processing to S35.

At S35, the laser control processor 30 transmits a result of the determination at S34 to the spectrum measurement control processor 60. The spectrum measurement control processor 60 controls the spectrum waveform adjuster 15a by driving the spectrum driver 64. For example, the spectrum measurement control processor 60 controls the spectrum waveform adjuster 15a to decrease the spectrum line width when the spectrum evaluation value V is larger than the target value Vt, and controls the spectrum waveform adjuster 15a to increase the spectrum line width when the spectrum evaluation value V is smaller than the target value Vt.

After S35, the laser control processor 30 returns processing to S32.

When the spectrum evaluation value V is in the allowable range at S34 (YES at S34), the laser control processor 30 ends processing of the present flowchart. Thereafter, the laser apparatus 1a continues outputting of a laser beam while setting of the spectrum waveform adjuster 15a is fixed. Alternatively, the laser control processor 30 may return processing to S32 and repeatedly perform the measurement and the determination of the spectrum evaluation value V while continuing outputting of a laser beam.

2.8.4 Spectrum Control Using Target Value Vt by Exposure Apparatus 100

FIG. 40 is a flowchart illustrating processing that the exposure apparatus 100 performs spectrum control by using the target value Vt. The processing illustrated in FIG. 40 corresponds to a second exemplary subroutine of S3 in FIG. 36.

At S36, the exposure control processor 110 transmits the target value Vt of the spectrum evaluation value V to the laser apparatus 1a. Having received the target value Vt, the laser apparatus 1a performs spectrum control by using the target value Vt. Operation of the laser apparatus 1a in this case may be the same as in FIG. 39.

After S36, the exposure control processor 110 ends processing of the present flowchart and returns to the processing illustrated in FIG. 36.

2.9 Effect

(1) According to the embodiment of the present disclosure, a method of controlling the spectrum waveform of a laser beam output from the laser apparatus 1a to the exposure apparatus 100 includes acquiring the longitudinal chromatic aberration K of the exposure apparatus 100, setting the target value Vt of the spectrum evaluation value V by using the relation between the longitudinal chromatic aberration K and the spectrum evaluation value V, and controlling the spectrum waveform by using the target value Vt.

With this configuration, since the longitudinal chromatic aberration K is acquired and the target value Vt of the spectrum evaluation value V is set, required exposure performance can be obtained by performing appropriate spectrum control in accordance with machine difference of the exposure apparatus 100.

(2) According to the embodiment, the acquiring the longitudinal chromatic aberration K includes outputting, by the laser apparatus 1a, a laser beam having the first wavelength λ₁ to the exposure apparatus 100; and receiving, by the laser apparatus 1a, the first focusing position Z₁ for the first wavelength λ₁ from the exposure apparatus 100. The acquiring the longitudinal chromatic aberration K also includes outputting, by the laser apparatus 1a, a laser beam having the second wavelength λ₂ different from the first wavelength λ₁ to the exposure apparatus 100; and receiving, by the laser apparatus 1a, the second focusing position Z₂ for the second wavelength λ₂ from the exposure apparatus 100. The acquiring the longitudinal chromatic aberration K also includes calculating the longitudinal chromatic aberration K by using the first and second wavelengths λ₁ and λ₂ and the first and second focusing positions Z₁ and Z₂.

With this configuration, since the laser apparatus 1a acquires the focusing positions for two wavelengths, the longitudinal chromatic aberration K of the exposure apparatus 100 can be accurately calculated.

(3) According to the embodiment, the acquiring the longitudinal chromatic aberration K includes transmitting, by the exposure apparatus 100, a setting signal for setting the first wavelength λ₁ to the laser apparatus 1a; and measuring, by the exposure apparatus 100, the first focusing position Z₁ for the first wavelength λ₁. The acquiring the longitudinal chromatic aberration K also includes transmitting, by the exposure apparatus 100, a setting signal for setting the second wavelength λ₂ different from the first wavelength λ₁ to the laser apparatus 1a; and measuring, by the exposure apparatus 100, the second focusing position Z₂ for the second wavelength λ₂. The acquiring the longitudinal chromatic aberration K also includes calculating the longitudinal chromatic aberration K by using the first and second wavelengths λ₁ and λ₂ and the first and second focusing positions Z₁ and Z₂.

With this configuration, since the exposure apparatus 100 measures the focusing positions for two wavelengths, the longitudinal chromatic aberration K of the exposure apparatus 100 can be accurately calculated.

(4) According to the embodiment, the acquiring the longitudinal chromatic aberration K includes calculating the longitudinal chromatic aberration K by using the first wavelength λ₁, the first focusing position Z₁ in the exposure apparatus 100 when a laser beam having the first wavelength λ₁ is incident on the exposure apparatus 100, the second wavelength λ₂ different from the first wavelength λ₁, and the second focusing position Z₂ in the exposure apparatus 100 when a laser beam having the second wavelength λ₂ is incident on the exposure apparatus 100.

With this configuration, the longitudinal chromatic aberration K of the exposure apparatus 100 can be accurately calculated by using the focusing positions for two wavelengths.

(5) According to the embodiment, the acquiring the longitudinal chromatic aberration K includes acquiring the ratio of the difference between the first and second focusing positions Z₁ and Z₂ relative to the difference between the first and second wavelengths λ₁ and λ₂.

With this configuration, the longitudinal chromatic aberration K can be acquired by simple calculation.

(6) According to the embodiment, the relation between the longitudinal chromatic aberration K and the spectrum evaluation value V is determined such that change of contrast in accordance with change of the longitudinal chromatic aberration K is smaller than change of contrast when the spectrum evaluation value V is fixed.

With this configuration, in another exposure apparatus 100 having a different longitudinal chromatic aberration K, as well, stable exposure performance can be obtained by controlling the spectrum evaluation value V.

(7) According to the embodiment, the relation between the longitudinal chromatic aberration K and the spectrum evaluation value V is determined such that the spectrum evaluation value V is inversely proportional to a power of the longitudinal chromatic aberration K with the power index N of one or more.

With this configuration, the spectrum evaluation value V can be set to an appropriate value in accordance with the longitudinal chromatic aberration K.

(8) According to the embodiment, the relation between the longitudinal chromatic aberration K and the spectrum evaluation value V is determined such that the spectrum evaluation value V is inversely proportional to the square of the longitudinal chromatic aberration K.

With this configuration, the spectrum evaluation value V can be set to a more appropriate value in accordance with the longitudinal chromatic aberration K.

(9) According to the embodiment, the relation between the longitudinal chromatic aberration K and the spectrum evaluation value V is stored in a table in which the longitudinal chromatic aberration K and the spectrum evaluation value V are associated with each other.

With this configuration, an appropriate spectrum evaluation value V can be set by searching the table based on the longitudinal chromatic aberration K.

(10) According to the embodiment, the spectrum waveform control method further includes acquiring the measured spectrum waveform O(λ) based on the interference pattern of a laser beam output from the laser apparatus 1a, and calculating the spectrum evaluation value V by using the measured spectrum waveform O(λ). The spectrum waveform is controlled by using the spectrum evaluation value V and the target value Vt.

With this configuration, since the spectrum waveform is controlled such that the spectrum evaluation value V acquired from the interference pattern approaches the target value Vt, the spectrum evaluation value V can be controlled to an appropriate value.

(11) According to the embodiment, the estimated spectrum waveform I(λ) representing the relation between the wavelength λ and light intensity is calculated by using the measured spectrum waveform O(λ), the barycenter wavelength λc included in the wavelength band of the estimated spectrum waveform I(λ) is calculated, and the spectrum evaluation value V is calculated by using an integral value obtained by integrating the product “I(λ) (λ−λc)²” of a function of a wavelength deviation from the barycenter wavelength λc and the light intensity with respect to the wavelength band.

With this configuration, an appropriate spectrum evaluation value V can be calculated for a laser beam having a spectrum waveform different from a spectrum waveform in a Gaussian distribution shape. Moreover, the spectrum waveform control is applicable to various shapes of an imaging pattern.

(12) According to the embodiment, the laser apparatus 1a connectable to the exposure apparatus 100 includes the laser oscillator 20 configured to output a laser beam, the spectrum waveform adjuster 15a configured to adjust the spectrum waveform of the laser beam, and the laser control processor 30. The laser control processor 30 acquires the longitudinal chromatic aberration K of the exposure apparatus 100, sets the target value Vt of the spectrum evaluation value V by using the relation between the longitudinal chromatic aberration K and the spectrum evaluation value V, and controls the spectrum waveform adjuster 15a by using the target value Vt.

With this configuration, since the longitudinal chromatic aberration K is acquired and the target value Vt of the spectrum evaluation value V is set, appropriate spectrum control can be performed in accordance with machine difference of the exposure apparatus 100.

(13) According to the embodiment, the laser control processor 30 controls the laser oscillator 20 to output a laser beam having the first wavelength λ₁ to the exposure apparatus 100, and receives the first focusing position Z₁ for the first wavelength λ₁ from the exposure apparatus 100. The laser control processor 30 also controls the laser oscillator 20 to output a laser beam having the second wavelength λ₂ different from the first wavelength λ₁ to the exposure apparatus 100, and receives the second focusing position Z₂ for the second wavelength λ₂ from the exposure apparatus 100. In addition, the laser control processor 30 calculates the longitudinal chromatic aberration K by using the first and second wavelengths λ₁ and λ₂ and the first and second focusing positions Z₁ and Z₂.

With this configuration, since the laser apparatus 1a acquires the focusing positions for two wavelengths, the longitudinal chromatic aberration K of the exposure apparatus 100 can be accurately calculated.

(14) According to the embodiment, the exposure apparatus 100 connectable to the laser apparatus 1a includes the projection optical system 102, the sensor 43, the stage 103, and the exposure control processor 110. The projection optical system 102 forms an image on the wafer surface by using a laser beam output from the laser apparatus 1a. The sensor 43 measures contrast on the wafer surface. The stage 103 moves the sensor 43 along the optical path axis of the laser beam. The exposure control processor 110 acquires the longitudinal chromatic aberration K of the exposure apparatus 100 by using the stage 103 and the sensor 43, sets the target value Vt of the spectrum evaluation value V by using the relation between the longitudinal chromatic aberration K and the spectrum evaluation value V of the laser beam, and transmits the target value Vt to the laser apparatus 1a.

With this configuration, since the longitudinal chromatic aberration K is acquired and the target value Vt of the spectrum evaluation value V is set, appropriate spectrum control can be performed in accordance with machine difference of the exposure apparatus 100.

(15) According to the embodiment, the exposure control processor 110 transmits a setting signal for setting the first wavelength λ₁ to the laser apparatus 1a and measures the first focusing position Z₁ for the first wavelength λ₁. The exposure control processor 110 also transmits a setting signal for setting the second wavelength λ₂ different from the first wavelength λ₁ to the laser apparatus 1a and measures the second focusing position Z₂ for the second wavelength λ₂. In addition, the exposure control processor 110 calculates the longitudinal chromatic aberration K by using the first and second wavelengths λ₁ and λ₂ and the first and second focusing positions Z₁ and Z₂.

With this configuration, since the exposure apparatus 100 measures the focusing positions for two wavelengths, the longitudinal chromatic aberration K of the exposure apparatus 100 can be accurately calculated.

### 3. Other

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A control method for a spectrum waveform of a laser beam output from a laser apparatus to an exposure apparatus, the method comprising:
acquiring a longitudinal chromatic aberration of the exposure apparatus;
setting a target value of an evaluation value of the spectrum waveform by using a relation between the longitudinal chromatic aberration and the evaluation value; and
controlling the spectrum waveform by using the target value.

2. The control method according to claim 1, wherein the acquiring the longitudinal chromatic aberration includes
outputting, by the laser apparatus, a laser beam having a first wavelength to the exposure apparatus,
receiving, by the laser apparatus, a first focusing position for the first wavelength from the exposure apparatus,
outputting, by the laser apparatus, a laser beam having a second wavelength different from the first wavelength to the exposure apparatus,
receiving, by the laser apparatus, a second focusing position for the second wavelength from the exposure apparatus, and
calculating the longitudinal chromatic aberration by using the first and second wavelengths and the first and second focusing positions.

3. The control method according to claim 1, wherein the acquiring the longitudinal chromatic aberration includes
transmitting, by the exposure apparatus, a setting signal for setting a first wavelength to the laser apparatus,
measuring, by the exposure apparatus, a first focusing position for the first wavelength,
transmitting, by the exposure apparatus, a setting signal for setting a second wavelength different from the first wavelength to the laser apparatus,
measuring, by the exposure apparatus, a second focusing position for the second wavelength, and
calculating the longitudinal chromatic aberration by using the first and second wavelengths and the first and second focusing positions.

4. The control method according to claim 1, wherein the acquiring the longitudinal chromatic aberration includes calculating the longitudinal chromatic aberration by using a first wavelength, a first focusing position in the exposure apparatus when a laser beam having the first wavelength is incident on the exposure apparatus, a second wavelength different from the first wavelength, and a second focusing position in the exposure apparatus when a laser beam having the second wavelength is incident on the exposure apparatus.

5. The control method according to claim 4, wherein the acquiring the longitudinal chromatic aberration includes acquiring a ratio of a difference between the first and second focusing positions relative to a difference between the first and second wavelengths.

6. The control method according to claim 1, wherein the relation is determined such that change of contrast in accordance with change of the longitudinal chromatic aberration is smaller than change of the contrast when the evaluation value is fixed.

7. The control method according to claim 1, wherein the relation is determined such that the evaluation value is inversely proportional to a power of the longitudinal chromatic aberration with a power index of one or more.

8. The control method according to claim 1, wherein the relation is determined such that the evaluation value is inversely proportional to a square of the longitudinal chromatic aberration.

9. The control method according to claim 1, wherein the relation is stored in a table in which the longitudinal chromatic aberration and the evaluation value are associated with each other.

10. The control method according to claim 1, further comprising:
acquiring a measured waveform based on an interference pattern of a laser beam output from the laser apparatus; and
calculating the evaluation value by using the measured waveform, wherein
the spectrum waveform is controlled by using the evaluation value and the target value.

11. The control method according to claim 10, wherein
the spectrum waveform representing a relation between a wavelength and light intensity is calculated by using the measured waveform,
a representative wavelength included in a wavelength band of the spectrum waveform is calculated, and
the evaluation value is calculated by using an integral value obtained by integrating a product of a function of a wavelength deviation from the representative wavelength and the light intensity with respect to the wavelength band.

12. A laser apparatus connectable to an exposure apparatus, the laser apparatus comprising:
a laser oscillator configured to output a laser beam;
a spectrum waveform adjuster configured to adjust a spectrum waveform of the laser beam; and
a processor configured to acquire a longitudinal chromatic aberration of the exposure apparatus, to set a target value of an evaluation value of the spectrum waveform by using a relation between the longitudinal chromatic aberration and the evaluation value, and to control the spectrum waveform adjuster by using the target value.

13. The laser apparatus according to claim 12, wherein the processor
controls the laser oscillator to output a laser beam having a first wavelength to the exposure apparatus,
receives a first focusing position for the first wavelength from the exposure apparatus,
controls the laser oscillator to output a laser beam having a second wavelength different from the first wavelength to the exposure apparatus,
receives a second focusing position for the second wavelength from the exposure apparatus, and
calculates the longitudinal chromatic aberration by using the first and second wavelengths and the first and second focusing positions.

14. The laser apparatus according to claim 12, wherein the relation is determined such that change of contrast in accordance with change of the longitudinal chromatic aberration is smaller than change of the contrast when the evaluation value is fixed.

15. The laser apparatus according to claim 12, wherein the relation is determined such that the evaluation value is inversely proportional to a power of the longitudinal chromatic aberration with a power index of 1 or more.

16. An exposure apparatus connectable to a laser apparatus, the exposure apparatus comprising:
a projection optical system configured to form an image on a wafer surface by using a laser beam output from the laser apparatus;
a sensor configured to measure contrast on the wafer surface;
a stage configured to move the sensor along an optical path axis of the laser beam; and
a processor configured to acquire a longitudinal chromatic aberration of the exposure apparatus by using the stage and the sensor, to set a target value of an evaluation value of a spectrum waveform of the laser beam by using a relation between the longitudinal chromatic aberration and the evaluation value, and to transmit the target value to the laser apparatus.

17. The exposure apparatus according to claim 16, wherein the processor
transmits a setting signal for setting a first wavelength to the laser apparatus,
measures a first focusing position for the first wavelength,
transmits a setting signal for setting a second wavelength different from the first wavelength to the laser apparatus,
measures a second focusing position for the second wavelength, and
calculates the longitudinal chromatic aberration by using the first and second wavelengths and the first and second focusing positions.

18. The exposure apparatus according to claim 16, wherein the relation is determined such that change of the contrast in accordance with change of the longitudinal chromatic aberration is smaller than change of the contrast when the evaluation value is fixed.

19. The exposure apparatus according to claim 16, wherein the relation is determined such that the evaluation value is inversely proportional to a power of the longitudinal chromatic aberration with a power index of 1 or more.

20. A method of manufacturing an electronic device, the method comprising:
acquiring a longitudinal chromatic aberration of an exposure apparatus;
setting a target value of an evaluation value of a spectrum waveform of a laser beam by using a relation between the longitudinal chromatic aberration and the evaluation value, the laser beam being output from a laser apparatus connected to the exposure apparatus;
outputting a laser beam generated by controlling the spectrum waveform by using the target value to the exposure apparatus; and
exposing a photosensitive substrate to the laser beam in the exposure apparatus to manufacture the electronic device.
